(19) United States
(12) Patent Application Publication
(10) Pub. No.: US 2024/0422985 A1
(43) Pub. Date: Dec. 19, 2024

(54) SEMICONDUCTOR MEMORY DEVICE

(71) Applicant: Kioxia Corporation, Tokyo (JP)

(72) Inventor: Tomoaki SHINO, Kamakura Kanagawa (JP)

(21) Appl. No.: 18/745,610

(22) Filed: Jun. 17, 2024

(30) Foreign Application Priority Data
Jun. 19, 2023 (JP) 2023-100347

(51) Int. Cl. H10B 43/40; G11C 16/30; H01L 23/00; H01L 25/065; H01L 25/18; H10B 43/27; H10B 80/00

(52) U.S. Cl. CPC H10B 43/40; G11C 16/30; H01L 24/08; H01L 25/0657; H01L 25/18; H10B 43/27; H10B 80/00; H01L 2224/08145; H01L 2924/1431; H01L 2924/14511

(57) ABSTRACT

A transistor for a semiconductor memory device includes a gate insulating film on a semiconductor substrate, a gate electrode on the gate insulating film, a side wall insulating film on both side surfaces of the gate electrode, a first diffusion layer disposed in the semiconductor substrate, connected to a contact electrode extending in a first direction intersecting a surface of the semiconductor substrate, and containing a first conductive-type impurity, a second diffusion layer disposed in the semiconductor substrate between the first diffusion layer and a region of the semiconductor substrate underneath the gate electrode, and containing the first conductive-type impurity, and a third diffusion layer disposed in the semiconductor substrate between the first diffusion layer and the second diffusion layer, connected to the second diffusion layer, and containing the first conductive-type impurity. A concentration of the second diffusion layer is higher than a concentration of the third diffusion layer.

### CROSS-REFERENCE TO RELATED APPLICATION(S)

This application is based upon and claims the benefit of priority from Japanese Patent Application No. 2023-100347, filed Jun. 19, 2023, the entire contents of which are incorporated herein by reference.

### FIELD

Embodiments described herein relate generally to a semiconductor memory device.

### BACKGROUND

A semiconductor memory device is known, which includes a semiconductor substrate and a plurality of transistors provided on the semiconductor substrate.

### DESCRIPTION OF THE DRAWINGS

FIG. 1 is a schematic block diagram showing a configuration of a memory die.

FIG. 2 is a schematic circuit diagram showing a configuration of a part of the memory die.

FIG. 3 is a schematic circuit diagram showing a configuration of a part of the memory die.

FIG. 4 is a schematic exploded perspective view showing a configuration example of a semiconductor memory device according to a first embodiment.

FIG. 5 is a schematic bottom view showing a configuration example of a memory chip.

FIG. 6 is a schematic cross-sectional view showing a configuration of a part of the memory die.

FIG. 7 is a schematic cross-sectional view showing a configuration of a part of the memory die.

FIG. 8 is a schematic bottom view showing a configuration of a part of the chip.

FIG. 9 is a schematic cross-sectional view showing a configuration of a part of the chip.

FIG. 10 is a schematic cross-sectional view showing a configuration of a part of the semiconductor memory device according to the first embodiment.

FIG. 11 is a schematic plan view showing a structure of an N-type high voltage transistor according to the first embodiment.

FIG. 12 is a schematic cross-sectional view showing the structure of the N-type high voltage transistor according to the first embodiment.

FIG. 13 is a schematic cross-sectional view showing an impurity concentration of the N-type high voltage transistor according to the first embodiment.

FIG. 14 is a schematic cross-sectional view showing a structure of a part of the N-type high voltage transistor according to the first embodiment.

FIG. 15 is a diagram conceptually showing an impurity concentration along a dotted line of A-A′ in a region shown in FIG. 11.

FIG. 16 is a schematic cross-sectional view showing a structure of a P-type high voltage transistor shown in FIG. 10.

FIG. 17 is a schematic cross-sectional view showing a structure of an N-type low voltage transistor shown in FIG. 10.

FIG. 18 is a schematic cross-sectional view showing a structure of a P-type low voltage transistor shown in FIG. 10.

FIG. 19 is a schematic cross-sectional view showing a structure of an N-type high voltage transistor according to a modification example of the first embodiment.

FIG. 20 is a schematic cross-sectional view showing a method of manufacturing the N-type high voltage transistor and the like according to the first embodiment.

FIG. 21 is a schematic cross-sectional view showing the method of manufacturing the N-type high voltage transistor and the like according to the first embodiment.

FIG. 22 is a schematic cross-sectional view showing the method of manufacturing the N-type high voltage transistor and the like according to the first embodiment.

FIG. 23 is a schematic cross-sectional view showing the method of manufacturing the N-type high voltage transistor and the like according to the first embodiment.

FIG. 24 is a schematic cross-sectional view showing the method of manufacturing the N-type high voltage transistor and the like according to the first embodiment.

FIG. 25 is a schematic cross-sectional view showing the method of manufacturing the N-type high voltage transistor and the like according to the first embodiment.

FIG. 26 is a schematic cross-sectional view showing the method of manufacturing the N-type high voltage transistor and the like according to the first embodiment.

FIG. 27 is a schematic cross-sectional view showing the method of manufacturing the N-type high voltage transistor and the like according to the first embodiment.

FIG. 28 is a schematic cross-sectional view showing the method of manufacturing the N-type high voltage transistor according to the first embodiment.

FIG. 29 is a schematic plan view showing the method of manufacturing the N-type high voltage transistor according to the first embodiment.

FIG. 30 is a schematic cross-sectional view showing the method of manufacturing the N-type high voltage transistor according to the first embodiment.

FIG. 31 is a schematic plan view showing the method of manufacturing the N-type high voltage transistor according to the first embodiment.

FIG. 32 is a schematic cross-sectional view showing the method of manufacturing the N-type high voltage transistor according to the first embodiment.

FIG. 33 is a schematic plan view showing the method of manufacturing the N-type high voltage transistor according to the first embodiment.

FIG. 34 is a schematic cross-sectional view showing the method of manufacturing the N-type high voltage transistor according to the first embodiment.

FIG. 35 is a schematic cross-sectional view showing the method of manufacturing the N-type high voltage transistor according to the first embodiment.

FIG. 36 is a schematic cross-sectional view showing the method of manufacturing the N-type high voltage transistor according to the first embodiment.

FIG. 37 is a schematic cross-sectional view showing a method of manufacturing the N-type low voltage transistor and the like according to the first embodiment.

FIG. 38 is a schematic cross-sectional view showing a method of manufacturing the N-type high voltage transistor according to the modification example of the first embodiment.

FIG. 39 is a schematic cross-sectional view showing the method of manufacturing the N-type high voltage transistor according to the modification example of the first embodiment.

FIG. 40 is a schematic cross-sectional view showing the method of manufacturing the N-type high voltage transistor according to the first embodiment.

FIG. 41 is a schematic cross-sectional view showing a structure of the N-type high voltage transistor according to a second embodiment.

FIG. 42 is a schematic plan view showing a well formation region in which the N-type high voltage transistor according to the second embodiment is configured.

FIG. 43 is a diagram conceptually showing an impurity concentration of an N-type high voltage transistor in a depth direction (Z direction) along a B-B′ dotted line in FIG. 41.

FIG. 44 is a schematic cross-sectional view showing a method of manufacturing the N-type high voltage transistor according to the second embodiment.

FIG. 45 is a schematic cross-sectional view showing the method of manufacturing the N-type high voltage transistor according to the second embodiment.

FIG. 46 is a schematic cross-sectional view showing the method of manufacturing the N-type high voltage transistor according to the second embodiment.

FIG. 47 is a schematic cross-sectional view showing the method of manufacturing the N-type high voltage transistor according to the second embodiment.

FIG. 48 is a schematic cross-sectional view showing the method of manufacturing the N-type high voltage transistor according to the second embodiment.

FIG. 49 is a schematic cross-sectional view showing the method of manufacturing the N-type high voltage transistor according to the second embodiment.

### DETAILED DESCRIPTION

Embodiments provide a semiconductor memory device that operates favorably.

In general, according to one embodiment, a semiconductor memory device includes a semiconductor substrate and a plurality of transistors provided on the semiconductor substrate. A first transistor among the plurality of transistors includes a first gate insulating film provided on the semiconductor substrate, a first gate electrode provided on the first gate insulating film, a side wall insulating film provided on both side surfaces of the first gate electrode, a first region disposed in the semiconductor substrate and provided at a position overlapping the first gate electrode when viewed in a first direction intersecting a surface of the semiconductor substrate, a first diffusion layer disposed in the semiconductor substrate, connected to a first contact electrode extending in the first direction, and containing a first conductive-type impurity, a second diffusion layer disposed in the semiconductor substrate, provided between the first region and the first diffusion layer, and containing the first conductive-type impurity, and a third diffusion layer disposed in the semiconductor substrate, provided between the second diffusion layer and the first diffusion layer, connected to the second diffusion layer, and containing the first conductive-type impurity. A concentration of the second diffusion layer is higher than a concentration of the third diffusion layer.

Next, the semiconductor memory device according to the embodiment will be described in detail with reference to the drawings. The following embodiment is merely an example, and is not intended to limit the scope of the present disclosure. In addition, the drawings below are schematic, and for convenience of explanation, some configurations and the like may not be shown. Moreover, the parts which are common to a plurality of embodiments may be given the same reference numerals, and the description thereof may not be given.

Further, the term “semiconductor memory device” used in the present specification may mean a memory die, or mean a memory system including a controller die such as a memory chip, a memory card, or a solid state drive (SSD). Additionally, the term “semiconductor memory device” may mean a configuration including a host computer such as a smartphone, a tablet terminal, or a personal computer.

In the present specification, when a first configuration is said to be “electrically connected” to a second configuration, the first configuration may be directly connected to the second configuration, or the first configuration may be connected to the second configuration via a wiring, a semiconductor member, a transistor, and the like. For example, when three transistors are connected in series, the first transistor is “electrically connected” to the third transistor even though the second transistor is in an OFF state.

In the present specification, a situation where the first configuration is said to be “connected between” the second configuration and the third configuration may mean that the first configuration, the second configuration, and the third configuration are connected in series and the second configuration is connected to the third configuration via the first configuration.

In the present specification, a situation where a circuit and the like are said to cause two wirings and the like to be “electrically connected” may mean, for example, that the circuit and the like include a transistor and the like, the transistor and the like are provided on a current path between the two wirings, and the transistor and the like are turned into an ON state.

In the present specification, a predetermined direction parallel to an upper surface of a substrate is referred to as an X direction, a direction which is parallel to the upper surface of the substrate and is perpendicular to the X direction is referred to as a Y direction, and a direction perpendicular to the upper surface of the substrate is referred to as a Z direction.

In the present specification, a direction along a predetermined surface may be referred to as a first direction, a direction intersecting the first direction along the predetermined surface may be referred to as a second direction, and a direction intersecting the predetermined surface may be referred to as a third direction. The first direction, the second direction, and the third direction may or may not correspond to any of the X direction, the Y direction, and the Z direction.

In the present specification, expressions such as “up” and “down” are relative to the substrate. For example, a direction away from the substrate along the Z direction is referred to as up, and a direction toward the substrate along the Z direction is referred to as down. When referring to a lower surface or a lower end of a certain configuration, it means a surface or an end portion on a side of the substrate of the configuration, and when referring to an upper surface or an upper end, it means a surface or an end portion on a side opposite to the substrate of the configuration. A surface intersecting the X direction or the Y direction is referred to as a side surface and the like.

Further, in the present specification, when referring to a “width”, a “length”, a “thickness”, and the like in a predetermined direction for a configuration, a member, and the like, it may mean the width, the length, the thickness, and the like in a cross section and the like observed by scanning electron microscopy (SEM), transmission electron microscopy (TEM), and the like.

In addition, in the present specification, when the term “wiring” is used, the term may include a wiring, a via contact electrode, a connection portion for connecting the wiring and the via contact electrode, a bonding electrode, and the like.

### First Embodiment

### Circuit Configuration of Memory Die MD

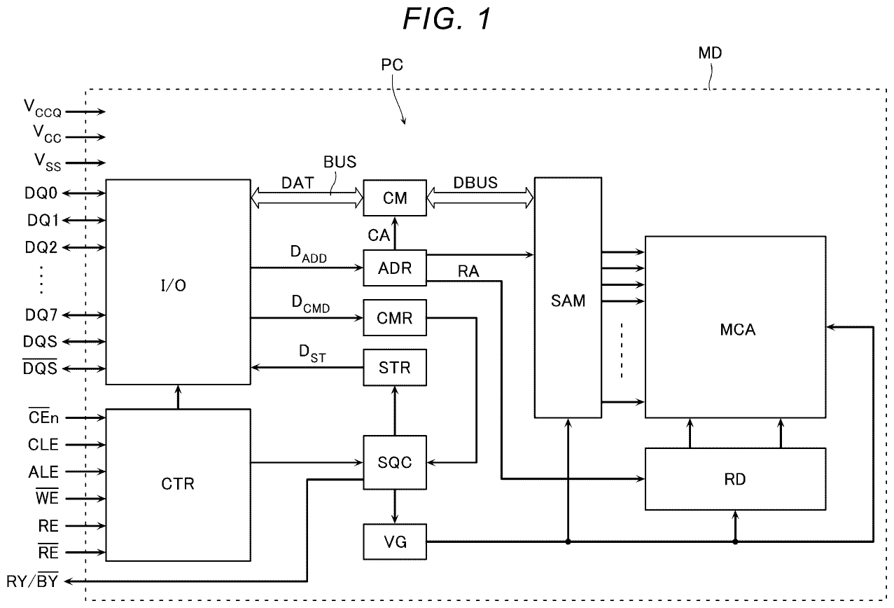

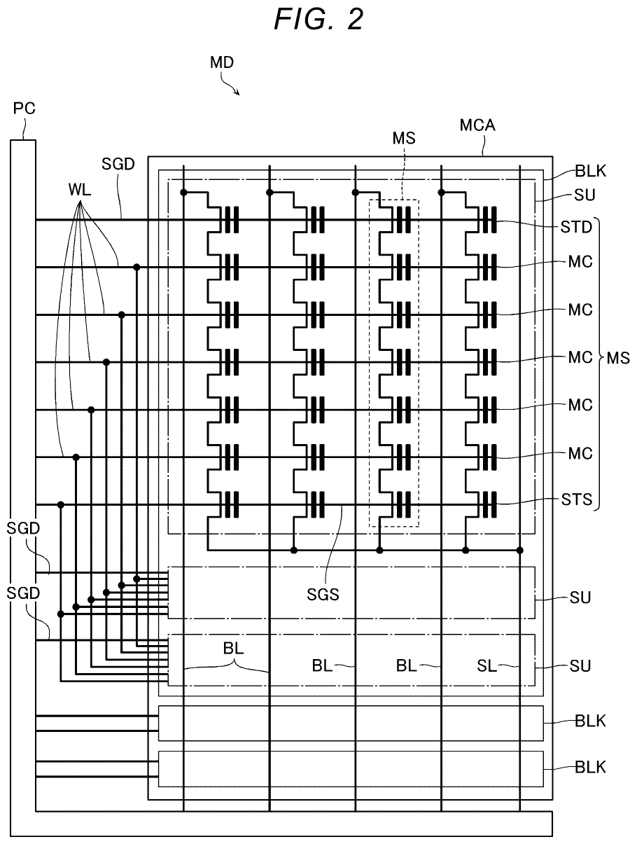

FIG. 1 is a schematic block diagram showing a configuration of a memory die MD according to a first embodiment. FIG. 2 is a schematic circuit diagram showing a configuration of a part of the memory die MD. FIG. 3 is a schematic circuit diagram showing a configuration of a part of the memory die MD.

FIG. 1 shows a plurality of control terminals and the like. The plurality of control terminals may be represented as control terminals corresponding to a high active signal (positive logic signal). The plurality of control terminals may be represented as control terminals corresponding to a low active signal (negative logic signal). The plurality of control terminals may be represented as control terminals corresponding to both the high active signal and the low active signal. In FIG. 1, the reference sign of the control terminal corresponding to the low active signal includes an overline. In the present specification, the reference sign of the control terminal corresponding to the low active signal includes a slash (“/”). A description of FIG. 1 is given as an example, and the specific form may be adjusted as appropriate. For example, a part or all of high active signals may be set to the low active signals, or a part or all of low active signals may be set to the high active signals.

As shown in FIG. 1, the memory die MD includes a memory cell array MCA and a peripheral circuit PC. The peripheral circuit PC includes a voltage generation circuit VG, a row decoder RD, a sense amplifier module SAM, and a sequencer SQC. The peripheral circuit PC further includes a cache memory CM, an address register ADR, a command register CMR, and a status register STR. The peripheral circuit PC further includes an input/output control circuit I/O and a logic circuit CTR.

### Circuit Configuration of Memory Cell Array MCA

As shown in FIG. 2, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes a drain-side select transistor STD, a plurality of memory cells (also referred to as memory transistors) MC, and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as a select transistor (STD, STS).

The memory cell MC is a field effect-type transistor. The memory cell MC includes a semiconductor layer, a gate insulating film, and a gate electrode. The semiconductor layer functions as a channel region. The gate insulating film includes a charge storage film. A threshold voltage of the memory cell MC is changed according to a charge quantity in the charge storage film. The memory cell MC stores data of one bit or a plurality of bits. A word line WL is connected to each of the gate electrodes of the plurality of memory cells MC corresponding to one memory string MS. Each of the word lines WL is commonly connected to all the memory strings MS in one memory block BLK.

The select transistors (STD, STS) are field effect-type transistors. Each of the select transistors (STD, STS) includes a semiconductor layer, a gate insulating film, and a gate electrode. The semiconductor layer functions as a channel region. The gate insulating film may include a charge storage layer. Select gate lines (SGD, SGS) are connected to each of the gate electrodes of the select transistors (STD, STS). One drain-side select gate line SGD is commonly connected to all of the memory strings MS in one string unit SU. One source-side select gate line SGS is commonly connected to all of the memory strings MS in one memory block BLK. Each of the drain-side select gate line SGD and the source-side select gate line SGS may be referred to as a select gate line SG.

### Circuit Configuration of Voltage Generation Circuit VG

The voltage generation circuit VG (FIG. 1) includes a plurality of voltage generation units vg1 to vg3, for example, as shown in FIG. 3. The voltage generation units vg1 to vg3 generate voltages of predetermined magnitudes in a read operation, a write operation, and an erasing operation, and output the generated voltages via voltage supply lines L_{VG1} to L_{VG3}. For example, the voltage generation unit vg1 outputs a program voltage V_{PGM} in the write operation. In addition, the voltage generation unit vg2 outputs a read pass voltage in the read operation. In addition, the voltage generation unit vg2 outputs a write pass voltage in the write operation. Hereinafter, the read pass voltage and the write pass voltage may be referred to as a non-selected voltage V_{USEL}. In addition, the voltage generation unit vg3 outputs a read voltage in the read operation. In addition, the voltage generation unit vg3 outputs a verify-voltage in the write operation. Hereinafter, the read voltage and the verify-voltage may be referred to as a select voltage V_{CGR}. The voltage generation units vg1 to vg3 may be, for example, a step-up circuit such as a charge pump circuit or a step-down circuit such as a regulator. Each of the step-down circuit and the step-up circuit is connected to a voltage supply line L_{P}. A power supply voltage V_{CC} or a ground voltage V_{SS} (FIG. 1) is supplied to the voltage supply line L_{P}. The voltage supply lines L_{P} are connected to, for example, the pad electrode P. An operation voltage, which is output from the voltage generation circuit VG, is appropriately adjusted according to the control signal from the sequencer SQC.

The voltage generation circuit VG (FIG. 1) described with reference to FIG. 3 has a configuration in which a program voltage, a read pass voltage, a write pass voltage, a read voltage, and a verify-voltage are generated, which are applied to the word line WL via a wiring CGI. Meanwhile, the voltage generation circuit VG may generate a plurality of operation voltages to be applied to the bit line BL, the source line SL, and the select gate lines (SGD, SGS) when the read operation, the write operation, and the erasing operation are performed with respect to the memory cell array MCA, in addition to the operation voltage to be applied to the word line WL, and may output the plurality of operation voltages to a plurality of voltage supply lines. The operation voltages are appropriately adjusted according to a control signal from the sequencer SQC.

### Circuit Configuration of Row Decoder RD

For example, as shown in FIG. 3, the row decoder RD (FIG. 1) includes a row control circuit RowC, a word line decoder WLD, a driver circuit DRV, and an address decoder (not shown). The row control circuit RowC includes a plurality of block decoder units blkd and a block decoder (not shown).

The plurality of block decoder units blkd are provided to respectively correspond to the plurality of memory blocks BLK in the memory cell array MCA. The block decoder unit blkd includes a plurality of word line switches WLSW. The plurality of word line switches WLSW are provided to respectively correspond to a plurality of word lines WL in the memory block BLK.

A word line switch WLSW is, for example, a field effect-type NMOS transistor. A drain electrode of the word line switch WLSW is connected to the word line WL. A source electrode of the word line switch WLSW is connected to the wiring CGI. The wiring CGI is connected to all the block decoder units blkd in the row control circuit RowC. A gate electrode of the word line switch WLSW is connected to the signal supply line BLKSEL. A plurality of signal supply lines BLKSEL are provided to respectively correspond to all the block decoder units blkd. In addition, the signal supply line BLKSEL is connected to all the word line switches WLSW in the block decoder unit blkd.

In the read operation, the write operation, and the like, for example, the signal supply line BLKSEL corresponding to one block decoder unit blkd that corresponds to a block address included in an address data D_{ADD} in the address register ADR (FIG. 1) enters an “H” state. In addition, the signal supply line BLKSEL corresponding to the rest of the block decoder unit blkd enters an “L” state. In addition, a voltage corresponding to the plurality of word lines WL is supplied to the wiring CGI. Thereby, a voltage is supplied to the word line WL in one memory block BLK corresponding to the above-described block address. In addition, the word lines WL in the other memory blocks BLK enters an electrically floating state.

The word line decoder WLD includes a plurality of word line decoding units wld. The plurality of word line decoding units wld are provided to respectively correspond to the plurality of memory cells MC in the memory string MS. In the example of FIG. 3, the word line decoding unit wld includes two transistors T_{WLS} and T_{WLU}. The transistors T_{WLS} and T_{WLU} are, for example, field effect-type NMOS transistors. The drain electrodes of the transistors T_{WLS} and T_{WLU} are connected to the wiring CGI. The source electrode of the transistor T_{WLS} is connected to wiring CGI_{S}. The source electrode of the transistor T_{WLU} is connected to wiring CGI_{U}. The gate electrode of the transistor T_{WLS} is connected to a signal line WLSEL_{S}. The gate electrode of the transistor T_{WLU} is connected to a signal line WLSEL_{U}. A plurality of signal lines WLSEL_{S} correspond to one transistor T_{WLS} disposed in all the word line decoding units wld. A plurality of signal lines WLSEL_{U} correspond to the other transistors T_{WLU} disposed in all the word line decoding units wld. Structures of the two transistors T_{WLS} and T_{WLU} provided in the word line decoder WLD will be described later.

In the read operation, the write operation, and the like, for example, the signal line WLSEL_{S} corresponding to the word line decoding unit wld that corresponds to a page address included in the address data D_{ADD} in the address register ADR (FIG. 1) enters an “H” state, and the WLSEL_{U} corresponding to this enters an “L” state. In addition, the signal line WLSEL_{S} corresponding to the rest of the word line decoding unit wld enters “L” state, and the WLSEL_{U} corresponding to this enters “H” state. Further, a voltage corresponding to the select word line WL is supplied to the wiring CGI_{S}. A voltage corresponding to a non-selected word line WL is supplied to the wiring CGI_{U}. Thus, the voltage corresponding to the select word line WL is supplied to one word line WL corresponding to the page address. In addition, the voltage corresponding to the non-selected word line WL is supplied to the other word lines WL.

The driver circuit DRV includes, for example, six transistors T_{DRV1} to T_{DRV6}. The transistors T_{DRV1} to T_{DRV6} are, for example, field effect-type NMOS transistors. The drain electrodes of the transistors T_{DRV1} to T_{DRV4} are connected to the wiring CGI_{S}. The drain electrodes of the transistors T_{DRV5} and T_{DRV6} are connected to the wiring CGI_{U}. The source electrode of the transistor T_{DRV1} is connected to an output terminal of the voltage generation unit vg1 via a voltage supply line L_{VG1}. The source electrodes of the transistors T_{DRV2} and T_{DRV5} are connected to an output terminal of the voltage generation unit vg2 via a voltage supply line L_{VG2}. The source electrode of the transistor T_{DRV3} is connected to an output terminal of the voltage generation unit vg3 via a voltage supply line L_{VG3}. The source electrodes of transistors T_{DRV4} and T_{DRV6} are connected to the pad electrode P via the voltage supply line L_{P}. The signal lines VSEL1 to VSEL6 are connected to the gate electrodes of the transistors T_{DRV1} to T_{DRV6}, respectively. Structures of the six transistors T_{DRV1 to} T_{DRV6} provided in the driver circuit DRV will be described later.

In the read operation, the write operation, and the like, for example, one of the plurality of signal lines VSEL1 to VSEL4 corresponding to the wiring CGI_{S} enters “H” state, and the other signal lines enter “L” state. In addition, one of the two signal lines VSEL5 and VSEL6 corresponding to the wiring CGI_{U} enters “H” state, and the other enters “L” state.

The address decoder (not shown) sequentially references row addresses RA of the address register ADR (FIG. 1) according to, for example, a control signal from the sequencer SQC (FIG. 1). The row address RA includes the block address and the page address described above. The address decoder controls the voltages of the signal lines BLKSEL, WLSEL_{S}, and WLSEL_{U} to “H” state or “L” state.

In the example of FIG. 3, the row decoder RD includes one block decoder unit blkd for each memory block BLK. Meanwhile, the configuration may be changed as appropriate. For example, one block decoder unit blkd may be provided for two or more memory blocks BLK.

### Circuit Configuration of Sense Amplifier Module SAM

The sense amplifier module SAM (FIG. 1) detects an ON state/OFF state of the memory cell MC and acquires data indicating the state of the memory cell MC. Such an operation may be referred to as a sense operation. The sense amplifier module SAM includes, for example, a plurality of sense amplifier units. The plurality of sense amplifier units are provided to respectively correspond to a plurality of bit lines BL. Each of the plurality of sense amplifier units includes a sense amplifier circuit and a latch circuit.

### Circuit Configuration of Cache Memory CM

The cache memory CM (FIG. 1) includes a plurality of latch circuits. The plurality of latch circuits are connected to the latch circuit in the sense amplifier module SAM via wiring DBUS. Pieces of data DAT included in the plurality of latch circuits are sequentially transferred to the sense amplifier module SAM or the input/output control circuit I/O.

A decoding circuit (not shown) and a switch circuit (not shown) are connected to the cache memory CM. The decoding circuit decodes a column address CA stored in the address register ADR. The switch circuit causes the latch circuit corresponding to the column address CA to be electrically connected to a bus BUS (FIG. 1) in accordance with the output signal of the decoding circuit.

### Circuit Configuration of Sequencer SOC

The sequencer SQC (FIG. 1) outputs an internal control signal to the row decoder RD, the sense amplifier module SAM, and the voltage generation circuit VG in accordance with command data D_{CMD} stored in the command register CMR. The sequencer SQC outputs status data D_{ST} indicating a state of the sequencer SQC itself to the status register STR as appropriate.

The sequencer SQC generates a ready/busy signal and outputs the generated ready/busy signal to a terminal RY/(/BY). During a period (busy period) in which the terminal RY/(/BY) is in the “L” state, access to the memory die MD is basically prohibited. During a period (ready period) in which the terminal RY/(/BY) is in the “H” state, the access to the memory die MD is permitted.

### Circuit Configuration of Input/Output Control Circuit I/O

The input/output control circuit I/O includes data signal input/output terminals DQ0 to DQ7, toggle signal input/output terminals DQS and/DQS, a plurality of input circuits, a plurality of output circuits, a shift register, and a buffer circuit. The plurality of input circuits, the plurality of output circuits, the shift register, and the buffer circuit are connected to terminals to which a power supply voltage V_{CCQ} and the ground voltage V_{SS} are supplied, respectively.

Data input via the data signal input/output terminals DQ0 to DQ7 is output from the buffer circuit to the cache memory CM, the address register ADR, or the command register CMR in accordance with the internal control signal from the logic circuit CTR. The data, which is output via the data signal input/output terminals DQ0 to DQ7, is input to the buffer circuit from the cache memory CM or the status register STR in accordance with the internal control signal from the logic circuit CTR.

The plurality of input circuits include, for example, comparators each connected to one of the data signal input/output terminals DQ0 to DQ7 or to both of the toggle signal input/output terminals DQS and/DQS. The plurality of output circuits include, for example, off chip driver (OCD) circuits each connected to one of the data signal input/output terminals DQ0 to DQ7 or to either of the toggle signal input/output terminals DQS and/DQS.

### Circuit Configuration of Logic Circuit CTR

The logic circuit CTR (FIG. 1) receives an external control signal from a controller die (not shown) via external control terminals/CEn, CLE, ALE, /WE, RE, and/RE, and outputs the internal control signal to the input/output control circuit I/O in response to the reception.

### Structure of Memory Die MD

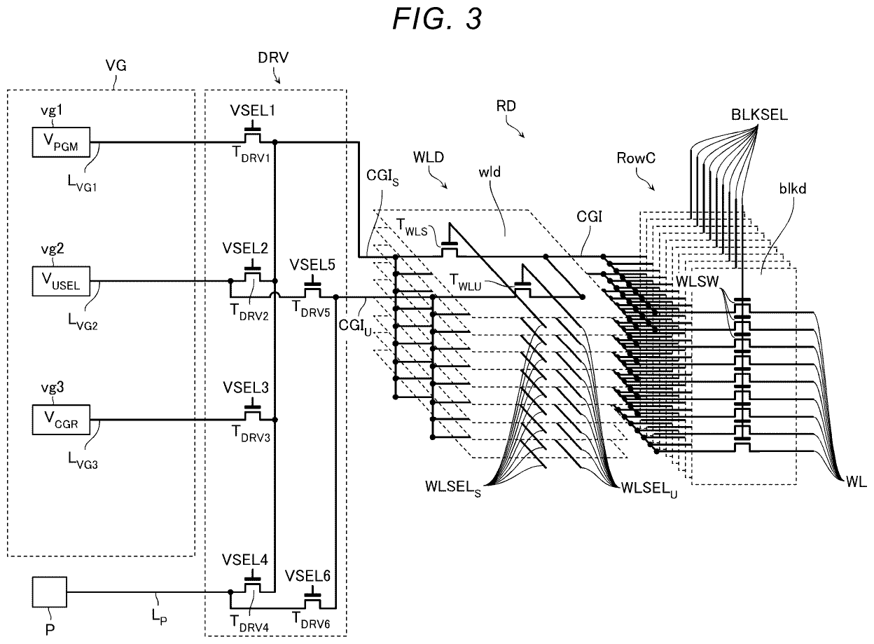

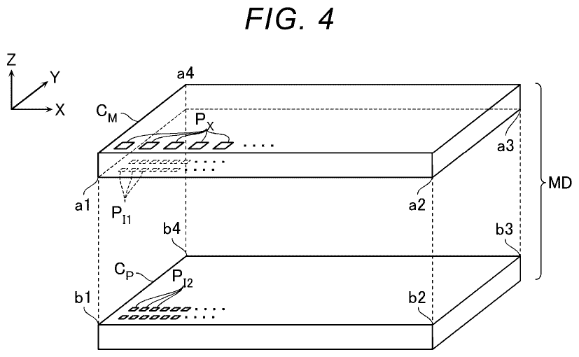

FIG. 4 is a schematic exploded perspective view showing a configuration example of a semiconductor memory device according to the first embodiment. As shown in FIG. 4, the memory die MD includes a chip C_{M} on a memory cell array MCA side and a chip C_{P} on a peripheral circuit PC side.

A plurality of external pad electrodes P_{X} to which a bonding wire (not shown) may be connected are provided on the upper surface of the chip C_{M}. A plurality of bonding electrodes P_{I1} are provided on the lower surface of the chip C_{M}. A plurality of bonding electrodes P_{I2} are provided on the upper surface of the chip C_{P}. Hereinafter, regarding the chip C_{M}, a surface on which the plurality of bonding electrodes P_{I1} are provided is referred to as a front surface, and a surface on which the plurality of external pad electrode P_{X} are provided is referred to as a rear surface. Regarding the chip C_{P}, a surface on which the plurality of bonding electrodes P_{I2} are provided is referred to as a front surface, and a surface on a side opposite to the front surface is referred to as a rear surface. In the example shown in the drawings, the front surface of the chip C_{P} is provided above the rear surface of the chip C_{P}, and the rear surface of the chip C_{M} is provided above the front surface of the chip C_{M}.

The chip C_{M} and the chip C_{P} are arranged so that the front surface of the chip C_{M} faces the front surface of the chip C_{P}. The plurality of bonding electrodes P_{I1} are provided respectively corresponding to the plurality of bonding electrodes P_{I2}, and are disposed at positions bondable to the plurality of bonding electrodes P_{I2}. The bonding electrodes P_{I1} and the bonding electrodes P_{I2} function as bonding electrodes for bonding the chip C_{M} and the chip C_{P} to each other and causing the chip C_{M} and the chip C_{P} to be electrically connected to each other.

In the example of FIG. 4, each of corner portions a1, a2, a3, and a4 of the chip C_{M} corresponds to respective corner portions b1, b2, b3, and b4 of the chip C_{P}.

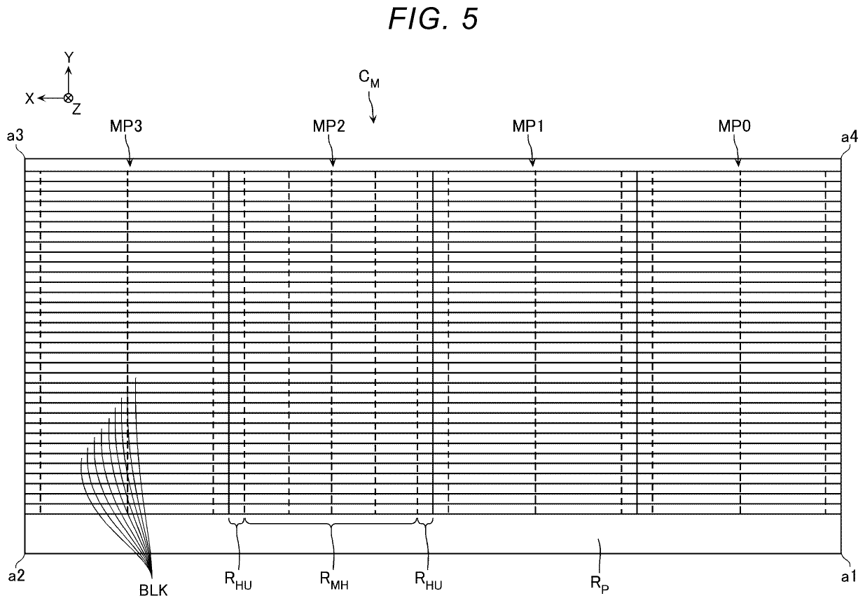

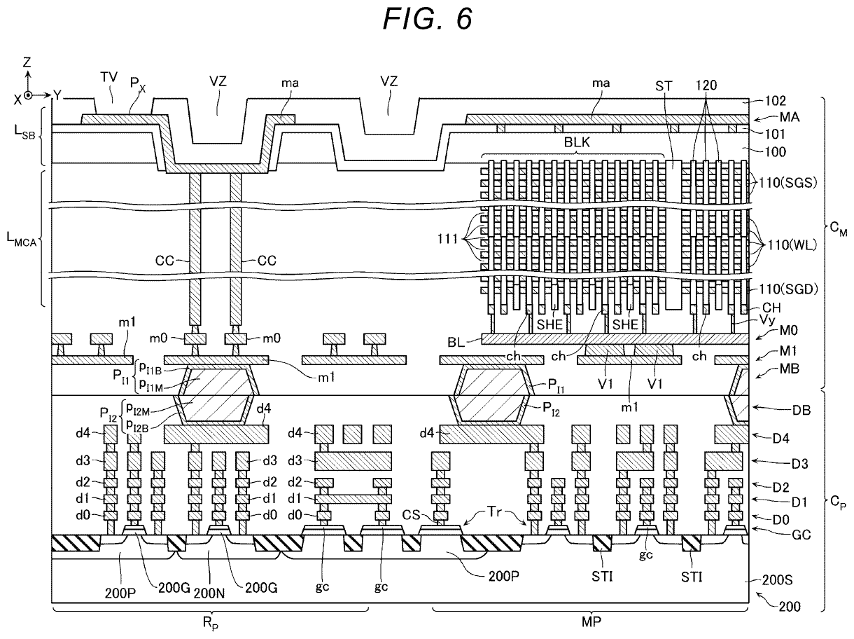

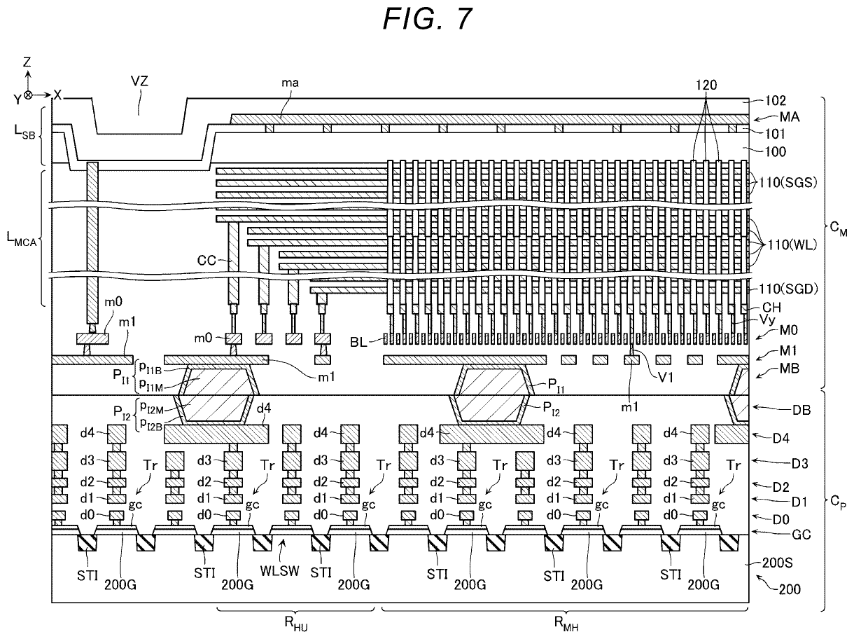

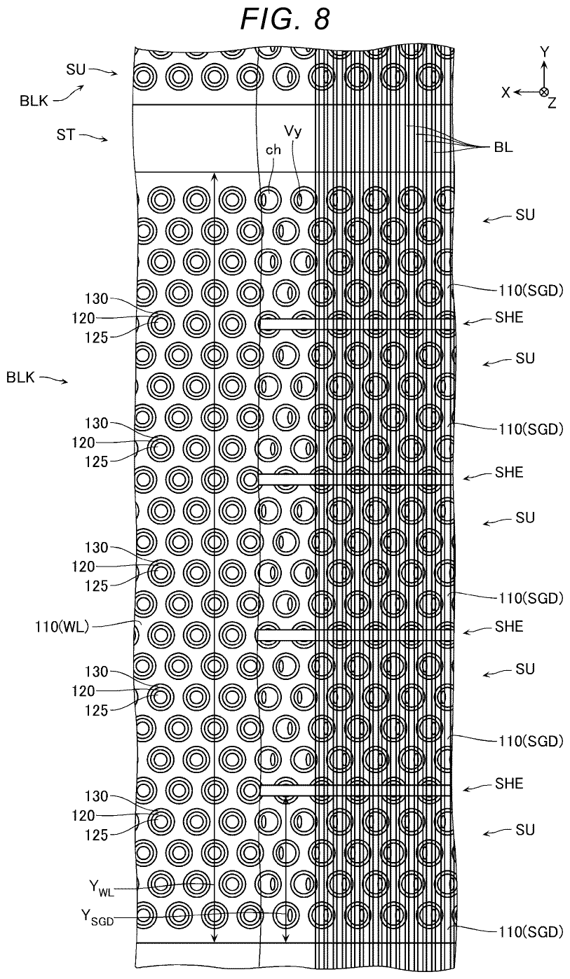

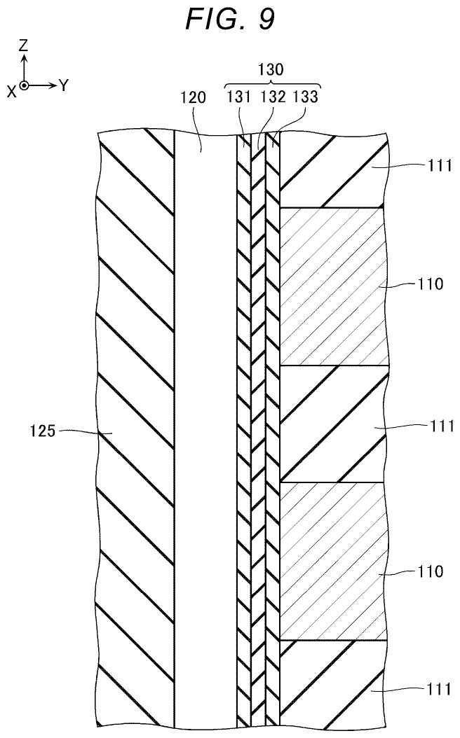

FIG. 5 is a schematic bottom view showing a configuration example of the chip C_{M}. In FIG. 5, a part of the configuration such as the bonding electrode P_{I1} is not shown. FIGS. 6 and 7 are schematic cross-sectional views showing a configuration of a part of the memory die MD. FIG. 8 is a schematic bottom view showing a configuration of a part of the chip C_{M}. In FIG. 8, an XY cross section at a height position corresponding to the word line WL is shown in a left-side region, and an XY cross section at a height position corresponding to the drain-side select gate line SGD is shown in a right-side region. In the right-side region in FIG. 8, via contact electrodes ch and Vy and the bit line BL are also shown in order to represent a connection portion between a semiconductor layer 120 and the bit line BL. In the left-side region in FIG. 8, the via contact electrodes ch and Vy and the bit line BL are also provided. FIG. 9 is a schematic cross-sectional view showing a configuration of a part of the chip C_{M}. Although FIG. 9 shows a YZ cross section, a structure similar to that in FIG. 9 is observed even when a cross section other than the YZ cross section (for example, an XZ cross section) along a central axis of a semiconductor layer 120 is observed.

### Structure of Chip C_{M}

In the example of FIG. 5, the chip C_{M} includes four memory planes MP0 to MP3 arranged in the X direction. The four memory planes MP0 to MP3 may be simply referred to as a memory plane MP. In addition, each of the four memory planes MP0 to MP3 includes a plurality of memory blocks BLK arranged in the Y direction. In addition, in the example of FIG. 5, each of the four memory planes MP0 to MP3 includes the hook up regions R_{HU} provided at both end portions in the X direction and a memory hole region R_{MH} (memory region) provided between the hook up regions R_{HU}. In addition, the chip C_{M} includes a peripheral region R_{P} provided on one end side in the Y direction with respect to the four memory planes MP0 to MP3.

In the example shown in the figure, the hook up regions R_{HU} are provided at both end portions of the memory plane MP in the X direction. Meanwhile, such a configuration is merely an example, and the specific configuration may be appropriately adjusted. For example, the hook up region R_{HU} may be provided at one end portion in the X direction instead of both end portions of the memory plane MP in the X direction. In addition, the hook up region R_{HU} may be provided at a central position or a position near the center of the memory plane MP in the X direction.

As shown in FIG. 6, the chip C_{M} includes, for example, a base layer L_{SB}, the memory cell array layer L_{MCA} provided below the base layer L_{SB}, a via contact electrode layer CH provided below the memory cell array layer L_{MCA}, a plurality of wiring layers M0 and M1 provided below the via contact electrode layer CH, and a chip bonding electrode layer MB provided below the wiring layers M0 and M1.

Structure of Base Layer L_{SB} of Chip C_{M}

For example, as shown in FIG. 6, the base layer L_{SB} includes a conductive layer 100 provided on an upper surface of the memory cell array layer L_{MCA}, an insulating layer 101 provided on an upper surface of the conductive layer 100, a rear surface wiring layer MA provided on an upper surface of the insulating layer 101, and an insulating layer 102 provided on an upper surface of the rear surface wiring layer MA.

The conductive layer 100 may include, for example, a semiconductor layer such as silicon (Si) into which an N-type impurity such as phosphorus (P) or a P-type impurity such as boron (B) is implanted, may include a metal such as tungsten (W), or may include a silicide such as tungsten silicide (WSi).

The conductive layer 100 functions as a part of the source line SL (FIG. 1). The conductive layer 100 is provided for the four memory planes MP0 to MP3 (FIG. 5). A region VZ not including the conductive layer 100 is provided at the end portions of the memory planes MP in the X direction and the Y direction.

The insulating layer 101 contains, for example, silicon oxide (SiO₂) and the like.

The rear surface wiring layer MA includes a plurality of wirings ma. The plurality of wirings ma may include, for example, aluminum (Al) and the like.

A part of the plurality of wirings ma function as a part of the source line SL (FIG. 2). Four wirings ma are provided to respectively correspond to the four memory planes MP0 to MP3 (FIG. 5). The wirings ma are each electrically connected to the conductive layer 100.

In addition, a part of the plurality of wirings ma function as the external pad electrode P_{X}. The wiring ma is provided in the peripheral region R_{P}. The wirings ma are connected to the via contact electrode CC in the memory cell array layer L_{MCA} in the region VZ not including the conductive layer 100. In addition, a part of the wiring ma is exposed to an outside of the memory die MD via an opening TV provided in the insulating layer 102.

The insulating layer 102 is a passivation layer configured with an insulating material such as polyimide.

Structure of Memory Cell Array Layer L_{MCA} of Chip C_{M} of in Memory Hole Region R_{M}H

As described with reference to FIG. 5, the plurality of memory blocks BLK arranged in the Y direction are provided in the memory cell array layer L_{MCA}. An inter-block insulating layer ST such as silicon oxide (SiO₂) is provided between two memory blocks BLK adjacent to each other in the Y direction, as shown in FIG. 6. A plurality of stacked structures arranged in the Y direction and including a plurality of conductive layers 110 arranged in the Z direction respectively correspond to the plurality of memory blocks BLK.

The memory block BLK includes, for example, the plurality of conductive layers 110 arranged in the Z direction and a plurality of semiconductor layers 120 extending in the Z direction, as shown in FIG. 6. In addition, as shown in FIG. 9, a gate insulating film 130 is provided between the plurality of conductive layers 110 and the plurality of semiconductor layers 120, respectively.

The conductive layer 110 has a substantially plate-like shape extending in the X direction. For example, the conductive layer 110 may include a stacked film of a barrier conductive film such as titanium nitride (TiN) and a metal film such as tungsten (W), molybdenum (Mo). The conductive layer 110 may contain, for example, polycrystalline silicon containing an impurity such as phosphorus (P) or boron (B). An interlayer insulating layer 111 such as silicon oxide (SiO₂) is provided between the plurality of conductive layers 110 arranged in the Z direction.

Among the plurality of conductive layers 110, one or the plurality of conductive layers 110 located in an uppermost layer function as the gate electrode of the source-side select transistor STS (FIG. 2) and the source-side select gate line SGS (refer to FIG. 6). The plurality of conductive layers 110 that function as the gate electrode of the source-side select transistor STS and the source-side select gate line SGS are electrically independent for each memory block BLK.

In addition, the plurality of conductive layers 110 located below the above-described conductive layers function as the gate electrode of the source-side select transistor STS and the source-side select gate line SGS, function as the gate electrodes and the word lines WL of the memory cells MC (FIG. 2). Each of the plurality of conductive layers 110 that function as the gate electrodes and the word lines WL of the memory cells MC is electrically independent for each memory block BLK.

In addition, one or the plurality of conductive layers 110 located below the above-described conductive layers that function as the gate electrodes and the word lines WL of the memory cells MC, function as the gate electrode of the drain-side select transistor STD and the drain-side select gate line SGD. For example, as shown in FIG. 8, a width Y_{SGD} of the plurality of conductive layers 110 in the Y direction is smaller than a width Y_{WL} of the conductive layer 110 functioning as the word line WL in the Y direction. In addition, an inter-string unit insulating layer SHE such as silicon oxide (SiO₂) is provided between the two conductive layers 110 adjacent to each other in the Y direction.

For example, as shown in FIG. 8, the semiconductor layers 120 are arranged in the X direction and the Y direction in a predetermined pattern. The semiconductor layers 120 function as channel regions of the plurality of memory cells MC and select transistors (STD, STS) provided in one memory string MS (FIG. 2), respectively. The semiconductor layer 120 contains, for example, polycrystalline silicon (Si). The semiconductor layer 120 has a substantially cylindrical shape, and an insulating layer 125 such as silicon oxide is provided at a central portion of the semiconductor layer 120. An outer peripheral surface of the semiconductor layer 120 is surrounded by each of the plurality of conductive layers 110, and faces the plurality of conductive layers 110.

In addition, an impurity region (not shown) is provided at an upper end of the semiconductor layer 120. The impurity region is connected to the above-described conductive layer 100 (refer to FIG. 6). The impurity region contains, for example, an N-type impurity such as phosphorus (P) or a P-type impurity such as boron (B).

In addition, an impurity region (not shown) is provided at a lower end of the semiconductor layer 120. The impurity region is connected to the bit line BL via the via contact electrode ch and the via contact electrode Vy. The impurity region contains, for example, an N-type impurity such as phosphorus (P).

The gate insulating film 130 has a substantially cylindrical shape covering the outer peripheral surface of the semiconductor layer 120, for example, as shown in FIG. 8. For example, as shown in FIG. 9, the gate insulating film 130 includes a tunnel insulating film 131, a charge storage film 132, and a block insulating film 133, which are stacked between the semiconductor layer 120 and the conductive layer 110. The tunnel insulating film 131 and the block insulating film 133 contain, for example, silicon oxide (SiO₂), silicon oxynitride (SiON), and the like. The charge storage film 132 includes, for example, a film such as silicon nitride (SiN) that is capable of storing charges. The tunnel insulating film 131, the charge storage film 132, and the block insulating film 133 have a substantially cylindrical shape, and extend in the Z direction along the outer peripheral surface of the semiconductor layer 120 except for a contact portion between the semiconductor layer 120 and the conductive layer 100.

FIG. 9 shows an example in which the gate insulating film 130 includes the charge storage film 132 such as silicon nitride. Meanwhile, the gate insulating film 130 may include, for example, a floating gate such as polycrystalline silicon containing an N-type or a P-type impurity.

Structure of Memory Cell Array Layer L_{MCA} of Chip C_{M} in Hook Up Region R_{HU}

As shown in FIG. 7, a plurality of via contact electrodes CC are provided in the hook up region R_{HU}. Each of a plurality of via contact electrodes CC extends in the Z direction and is connected to the conductive layers 110 (WL, SGD, and SGS) at the upper end.

Structure of Memory Cell Array Layer L_{MCA} of Chip C_{M} in Peripheral Region R_{P}

For example, as shown in FIG. 6, the plurality of via contact electrodes CC are provided in the peripheral region R_{P} corresponding to the external pad electrode P_{X}. The plurality of via contact electrodes CC are connected to the external pad electrode P_{X} at the upper end.

### Structure of Via Contact Electrode Layer CH

For example, the plurality of via contact electrodes ch provided in the via contact electrode layer CH are electrically connected to at least one of a configuration in the memory cell array layer L_{MCA} and a configuration in the chip C_{P}.

The via contact electrode layer CH includes the plurality of via contact electrodes ch. The plurality of via contact electrodes ch may include, for example, a stacked film of a barrier conductive film such as titanium nitride (TiN) and a metal film such as tungsten (W). The via contact electrodes ch are provided to respectively correspond to the plurality of semiconductor layers 120 and are connected to lower ends of the plurality of semiconductor layers 120.

### Structure of Wiring Layers M0 and M1 of Chip C_{M}

For example, a plurality of wirings provided in the wiring layers M0 and M1 are electrically connected to at least one of the configuration in the memory cell array layer L_{MCA} and the configuration in the chip C_{P}.

The wiring layer M0 includes a plurality of wirings m0. The plurality of wirings m0 may include, for example, a stacked film of a barrier conductive film such as titanium nitride (TiN), tantalum nitride (TaN), or a stacked film of tantalum nitride (TaN) and tantalum (Ta), and a metal film such as copper (Cu). Some of the plurality of wirings m0 function as the bit lines BL. The bit lines BL are arranged in the X direction and extend in the Y direction, for example, as shown in FIG. 8.

For example, as shown in FIG. 6, the wiring layer M1 includes a plurality of wirings ml. The plurality of wirings ml may include, for example, a stacked film of a barrier conductive film such as titanium nitride (TiN) and a metal film such as tungsten (W). In addition, the plurality of wirings ml are electrically connected to the wiring m0 via a via contact electrode V1, for example, as shown in FIGS. 6 and 7.

### Structure of Chip Bonding Electrode Layer MB

A plurality of wirings provided in the chip bonding electrode layer MB are electrically connected to at least one of the configuration in the memory cell array layer L_{MCA} and the configuration in the chip C_{P}, for example.

The chip bonding electrode layer MB includes a plurality of bonding electrodes P_{I1} (also referred to as bonding pads). The plurality of bonding electrodes P_{I1} may include, for example, a stacked film of a barrier conductive film p_{I1B} such as titanium nitride (TiN), tantalum nitride (TaN), or a stacked film of tantalum nitride (TaN) and tantalum (Ta), and a metal film p_{I1M} such as copper (Cu).

In addition, the chip C_{P} includes, for example, a semiconductor substrate 200, an electrode layer GC provided above the semiconductor substrate 200, wiring layers D0, D1, D2, D3, and D4 provided above the electrode layer GC, and the chip bonding electrode layer DB provided above the wiring layers D0, D1, D2, D3, and D4, as shown in FIG. 6.

### Structure of Semiconductor Substrate 200 of Chip C_{P}

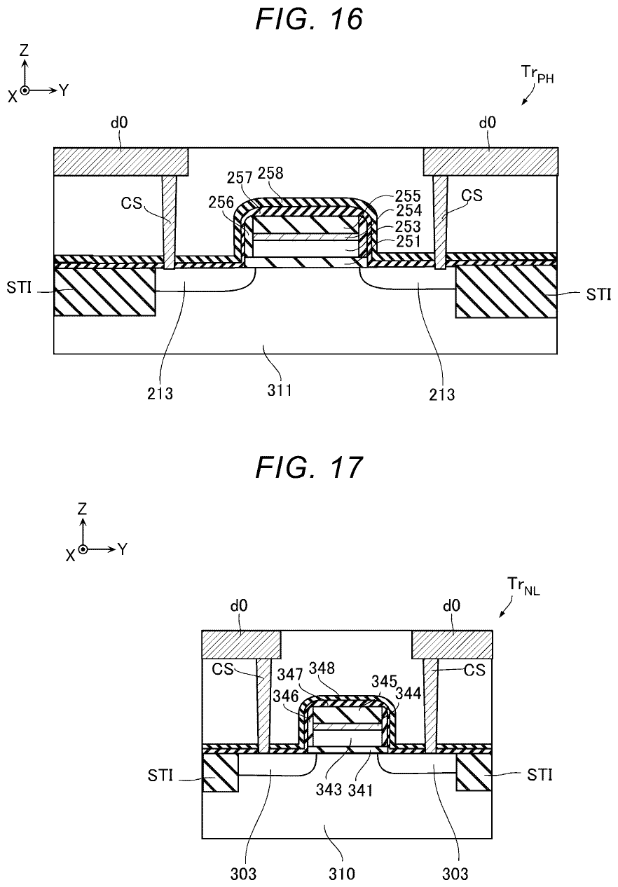

The semiconductor substrate 200 contains P-type silicon (Si) containing a P-type impurity such as boron (B), for example. On a surface of the semiconductor substrate 200, for example, an N-type well region 200N containing an N-type impurity such as phosphorus (P), a P-type well region 200P containing a P-type impurity such as boron (B), a semiconductor substrate region 200S in which the N-type well region 200N and the P-type well region 200P are not provided, and an insulating region STI are provided. A part of the P-type well region 200P is provided in the semiconductor substrate region 200S, and a part of the P-type well region 200P is provided in the N-type well region 200N (as shown in FIG. 16). Each of the N-type well region 200N, the P-type well region 200P provided in the N-type well region 200N and the semiconductor substrate region 200S, and the semiconductor substrate region 200S functions as a part of a plurality of transistors Tr and a plurality of capacitors configuring the peripheral circuit PC. A part of the plurality of transistors Tr functions as the word line switch WLSW. The insulating region STI includes, for example, silicon oxide (SiO₂) and extends in the Z direction from the surface of the semiconductor substrate 200.

### Structure of Electrode Layer GC of Chip C_{P}

An electrode layer GC is provided on an upper surface of the semiconductor substrate 200 with an insulating layer 200G sandwiched therebetween. The electrode layer GC includes a plurality of electrodes gc that face the surface of the semiconductor substrate 200. Each of the regions of the semiconductor substrate 200 and the plurality of electrodes gc, which are provided in the electrode layer GC, is connected to a via contact electrode CS.

Each of the N-type well region 200N of the semiconductor substrate 200, the P-type well region 200P provided in the N-type well region 200N and the semiconductor substrate region 200S, and the semiconductor substrate region 200S functions as channel regions of the plurality of transistors Tr, one electrode of the plurality of capacitors configuring the peripheral circuit PC, and the like.

The plurality of electrodes gc provided in the electrode layer GC function as gate electrodes of the plurality of transistors Tr of the peripheral circuit PC, and the other electrode of the plurality of capacitors, respectively.

The via contact electrode CS extends in the Z direction and is connected to the upper surface of the semiconductor substrate 200 or the upper surface of the electrode gc at the lower end of the via contact electrode CS. An impurity region containing an N-type impurity or a P-type impurity is provided at a connection portion between the via contact electrode CS and the semiconductor substrate 200. The via contact electrode CS may include, for example, a stacked film of a barrier conductive film such as titanium nitride (TiN) and a metal film such as tungsten (W).

### Structure of Wiring Layers D0, D1, D2, D3, and D4 of Chip C_{P}

For example, as shown in FIG. 6, a plurality of connection portions and a plurality of wirings provided in D0, D1, D2, D3, and D4 are electrically connected to at least one of the configuration in the memory cell array layer L_{MCA} and the configuration in the chip C_{P}.

Each of the wiring layers D0, D1, and D2 includes a plurality of connection portions d0, d1, and d2 and a plurality of wirings. The plurality of connection portions d0, d1, and d2 and the plurality of wirings may include, for example, a stacked film of a barrier conductive film such as titanium nitride (TiN) and a metal film such as tungsten (W).

Each of the wiring layers D3 and D4 includes a plurality of connection portions d3 and d4 and a plurality of wirings. The plurality of connection portions d3, d4 and the plurality of wirings may include, for example, a stacked film of a barrier conductive film such as titanium nitride (TiN), tantalum nitride (TaN), or a stacked film of tantalum nitride (TaN) and tantalum (Ta), and a metal film such as copper (Cu).

### Structure of Chip Bonding Electrode Layer DB

For example, the plurality of wirings provided in the chip bonding electrode layer DB are electrically connected to at least one of the configuration in the memory cell array layer L_{MCA} and the configuration in the chip C_{P}.

The chip bonding electrode layer DB includes a plurality of bonding electrodes P_{I2}. The plurality of bonding electrodes P_{I2} may include, for example, a stacked film of a barrier conductive film p_{I2B} such as titanium nitride (TiN), tantalum nitride (TaN), or a stacked film such as tantalum nitride (TaN) and tantalum (Ta), and a metal film p_{I2M} such as copper (Cu).

When the metal films p_{I1M} and p_{I2M} of copper (Cu) and the like are used for the bonding electrode P_{I1} and the bonding electrode P_{I2}, the metal film p_{I1M} and the metal film p_{I2M} are integrated with each other, and it is difficult to check the boundary therebetween. However, the bonded structure may be checked by the distortion of the bonded shape of the bonding electrode P_{I1} and the bonding electrode P_{I2} due to the positional misalignment and the positional misalignment (generation of a discontinuous portion on the side surface) of the barrier conductive films p_{I1B} and p_{I2B}. In addition, when the bonding electrode Pr and the bonding electrode P_{I2} are formed by the damascene method, each of the side surfaces has a tapered shape. Therefore, a side wall shape of the cross section in the Z direction of a portion where the bonding electrode P_{I1} and the bonding electrode P_{I2} are bonded is not a linear shape, and is a non-rectangular shape. In addition, when the bonding electrode P_{I1} and the bonding electrode P_{I2} are bonded, the structure is such that the bottom surface, the side surface, and the upper surface of each Cu forming the bonding electrode P_{I1} and the bonding electrode P_{I2} are covered with the barrier metal. In contrast, in a wiring layer using general Cu, an insulating layer (SiN, SiCN, and the like) having an oxidation preventing function of Cu is provided on the upper surface of Cu, and the barrier metal is not provided. Therefore, it is possible to distinguish the wiring layer from a general wiring layer even when no positional misalignment in bonding occurs.

### Structure of Transistor Tr

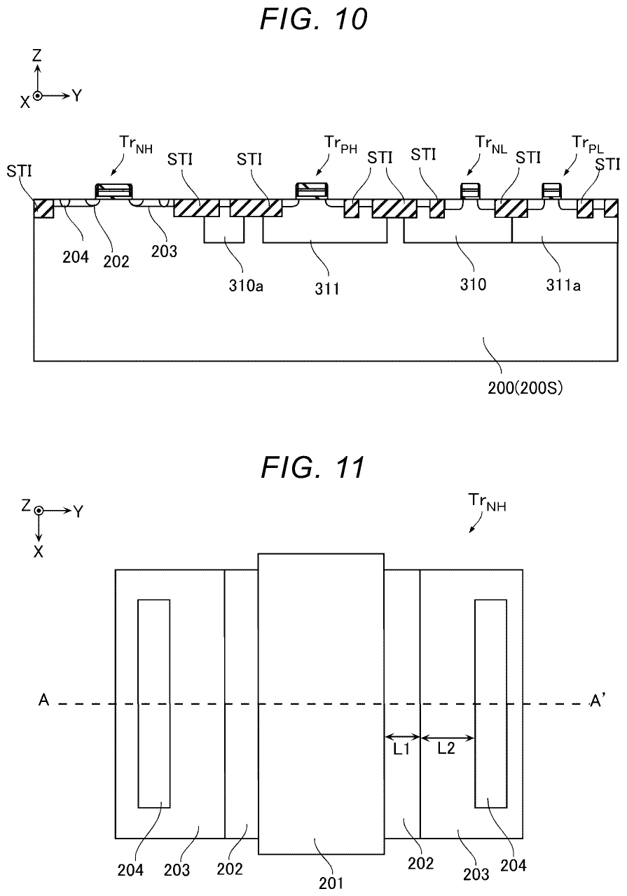

FIG. 10 is a schematic cross-sectional view showing a configuration of a part of the semiconductor memory device according to the first embodiment. FIG. 10 shows an example of structures of the plurality of transistors Tr provided in the semiconductor substrate region 200S according to the present embodiment.

As shown in FIG. 10, on the surface of the semiconductor substrate 200, P-type well regions 310a and 310 containing a P-type impurity such as boron (B), N-type well regions 311a and 311 containing an N-type impurity such as phosphorus (P), the semiconductor substrate region 200S in which the N-type well regions 311a and 311 and the P-type well regions 310a and 310 are not provided, and the insulating region STI. The P-type well regions 310a and 310 are an example of the P-type well region 200P described with reference to FIG. 6. The N-type well regions 311a and 311 are an example of the N-type well region 200N described with reference to FIG. 6.

As described with reference to FIGS. 6 and 7, the plurality of transistors Tr are provided on the semiconductor substrate 200 of the chip C_{P}. The plurality of transistors Tr include a plurality of N-type high voltage transistors Tr_{NH}, a plurality of P-type high voltage transistors Tr_{PH}, a plurality of N-type low voltage transistors Tr_{NL}, and a plurality of P-type low voltage transistors Tr_{PL}. The P-type high voltage transistor Tr_{PH}, the N-type low voltage transistor Tr_{NL}, and the P-type low voltage transistor Tr_{PL} are provided on the same semiconductor substrate 200 as that of the high voltage transistor Tr_{NH}. A voltage higher than 10 V may be supplied to the high voltage transistors Tr_{NH} and Tr_{PH}, for example. The high voltage transistor Tr_{NH} is provided in, for example, the row decoder RD. For example, the two transistors T_{WLS} and T_{WLU} in the word line decoder WLD described with reference to FIG. 3 are high voltage transistors such as the high voltage transistor Tr_{NH}. In addition, for example, the six transistors T_{DRV1} to T_{DRV6} in the driver circuit DRV described with reference to FIG. 3 are high voltage transistors such as the high voltage transistor Tr_{NH}.

Hereinafter, structures of the N-type high voltage transistor Tr_{NH}, the P-type high voltage transistor Tr_{PH}, the N-type low voltage transistor Tr_{NL}, and the P-type low voltage transistor Tr_{PL} will be described in order.

### Structure of High Voltage Transistor Tr_{NH}

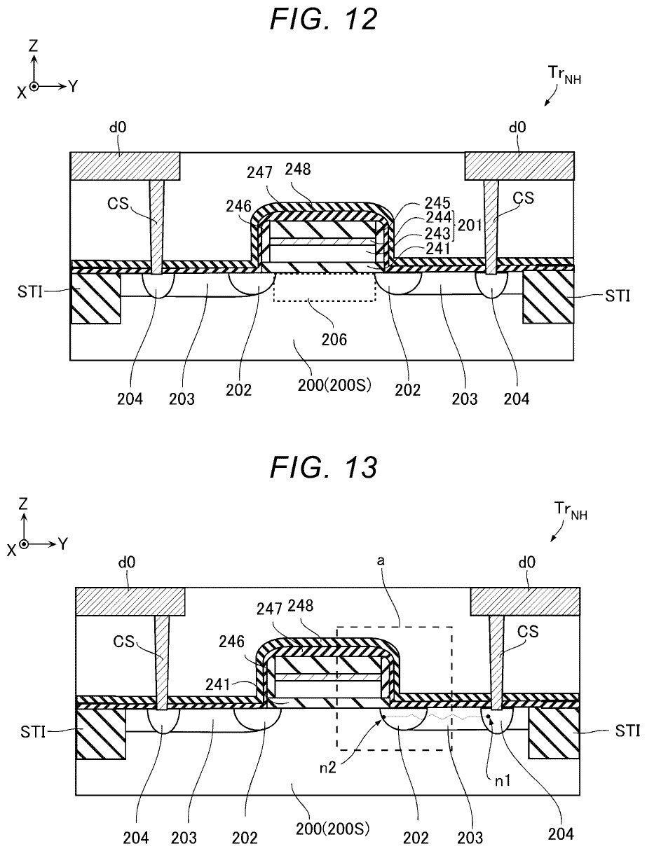

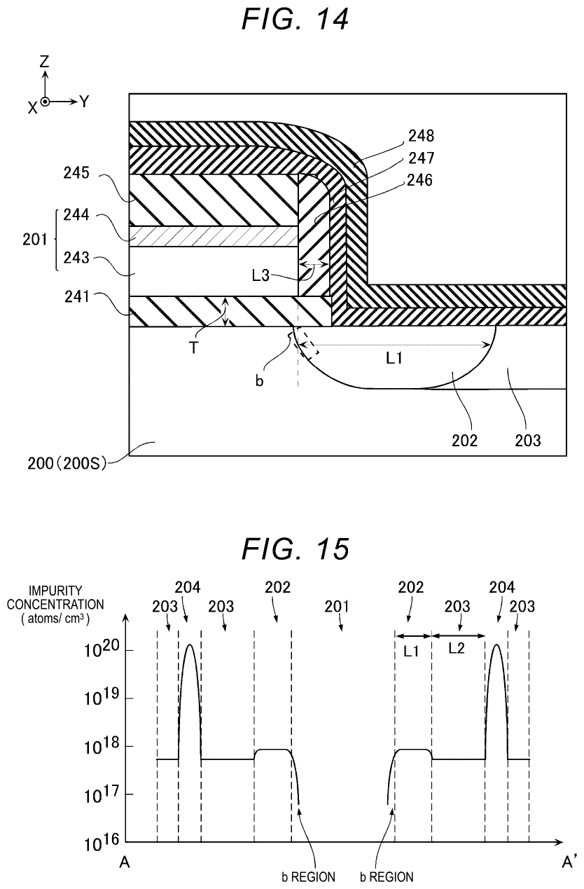

FIG. 11 is a schematic plan view showing a structure of the N-type high voltage transistor Tr_{NH} according to the first embodiment. FIG. 12 is a schematic cross-sectional view showing the structure of the N-type high voltage transistor Tr_{NH} according to the first embodiment. FIG. 12 is a view when the structure shown in FIG. 11 is cut along a dotted line A-A′. FIG. 13 is a view showing an impurity concentration of the N-type high voltage transistor Tr_{NH} according to the first embodiment. FIG. 14 is a cross-sectional view showing a structure of a part of the N-type high voltage transistor Tr_{NH} according to the first embodiment. FIG. 14 is a cross-sectional view when a region in FIG. 13 is enlarged. FIG. 15 is a diagram conceptually showing an impurity concentration along a dotted line of A-A′ in a region shown in FIG. 11. FIG. 15 shows an impurity concentration of an N-type impurity such as phosphorus (P) or arsenic (As).

The high voltage transistor Tr_{NH} is provided in the semiconductor substrate region 200S of the semiconductor substrate 200, for example, as shown in FIG. 12 and the like. As shown in FIGS. 12 and 14, for example, the high voltage transistor Tr_{NH} includes a part of the semiconductor substrate region 200S, a gate insulating film 241 such as silicon oxide (SiO₂) provided on the surface of the semiconductor substrate 200, a gate electrode member 243 such as polycrystalline silicon (Si) provided on an upper surface of the gate insulating film 241, a gate electrode member 244 such as tungsten (W) provided on an upper surface of the gate electrode member 243, a cap insulating layer 245 such as silicon oxide (SiO₂) or silicon nitride (Si₃N₄) provided on an upper surface of the gate electrode member 244, and a side wall insulating film 246 such as silicon oxide (SiO₂) or silicon nitride (Si₃N₄) provided on side surfaces of the gate electrode member 243, the gate electrode member 244, and the cap insulating layer 245 in the X direction or the Y direction. The gate electrode member 243 contains, for example, an N-type impurity such as phosphorus (P) or arsenic (As), or a P-type impurity such as boron (B). The gate electrode member 243 and the gate electrode member 244 are one of the plurality of electrodes gc described with reference to FIG. 6 and the like, and function as the gate electrode 201 provided on the gate insulating film 241. The gate insulating film 241 is one of a plurality of insulating layers 200G described with reference to FIG. 6 and the like.

As shown in FIGS. 12 and 14, for example, the high voltage transistor Tr_{NH} includes a liner insulating layer 247 such as silicon oxide (SiO₂) and a liner insulating layer 248 such as silicon nitride (Si₃N₄), which are stacked on the surface of the semiconductor substrate 200, a side surface of the gate insulating film 241 in the X direction or the Y direction, a side surface of the side wall insulating film 246 in the X direction or the Y direction, and an upper surface of the cap insulating layer 245.

For example, as shown in FIG. 12, the via contact electrode CS extending in the Z direction is connected to the high voltage transistor Tr_{NH}. The via contact electrode CS may include, for example, a stacked film of a barrier conductive film such as titanium nitride (TiN) and a metal film such as tungsten (W). The via contact electrode CS is connected to the surface of the semiconductor substrate 200 by penetrating the liner insulating layer 247 and the liner insulating layer 248, and functions as a source electrode or a drain electrode of the high voltage transistor Tr_{NH}. The via contact electrode CS (not shown) penetrates the liner insulating layer 248, the liner insulating layer 247, and the cap insulating layer 245 and is connected to the upper surface of the gate electrode member 244. The via contact electrode CS (not shown) functions as a part of the gate electrode of the high voltage transistor Tr_{NH}.

As shown in FIG. 12 and the like, the high voltage transistor Tr_{NH} has a channel region 206 on a surface of the semiconductor substrate 200 facing the gate electrode member 243. In other words, the channel region 206 is a region disposed in the semiconductor substrate 200 and provided at a position overlapping the gate electrode 201 when viewed in the Z direction intersecting the surface of the semiconductor substrate 200. In addition, for example, as shown in FIGS. 11, 12, and the like, a high-concentration N− diffusion layer 202, a low-concentration N-diffusion layer 203, and an N+ diffusion layer 204 are provided on the surface of the semiconductor substrate 200. For example, in FIG. 11, the high-concentration N− diffusion layer 202, the low-concentration N− diffusion layer 203, and the N+ diffusion layer 204 on a left side function as a source region, and the high-concentration N− diffusion layer 202, the low-concentration N− diffusion layer 203, and the N+ diffusion layer 204 on a right side function as a drain region.

The N+ diffusion layer 204 is a diffusion layer region, which is provided in the semiconductor substrate 200, connected to the via contact electrode CS extending in the Z direction, and containing a first conductive-type impurity. The first conductive-type impurity is, for example, an N-type impurity such as phosphorus (P) or arsenic (As). An impurity concentration of the N− type impurity contained in the N+ diffusion layer 204 is higher than an impurity concentration of the N-type impurity contained in the high-concentration N− diffusion layer 202 and the low-concentration N− diffusion layer 203.

The high-concentration N− diffusion layer 202 is a diffusion layer region disposed in the semiconductor substrate 200, provided between the channel region 206 and the N+ diffusion layer 204, and containing the first conductive-type impurity. At least a part of the high-concentration N− diffusion layer 202 is provided at a position overlapping the side wall insulating film 246 when viewed in in the Z direction. A b region shown in FIG. 14 is a region provided at a position overlapping the channel region 206 when viewed in the Z direction, and may also be referred to as an overlap region. The impurity concentration of the N-type impurity contained in the high-concentration N− diffusion layer 202 is higher than the impurity concentration of the N− type impurity contained in the low-concentration N− diffusion layer 203. In addition, the impurity concentration of the N-type impurity contained in the high-concentration N− diffusion layer 202 is lower than the impurity concentration of the N-type impurity contained in the N+ diffusion layer 204.

The low-concentration N− diffusion layer 203 is a diffusion layer region, which is disposed in the semiconductor substrate 200, provided between the high-concentration N− diffusion layer 202 and the N+ diffusion layer 204, connected to the high-concentration N− diffusion layer 202, and containing the first conductive-type impurity.

Here, a peak of an impurity concentration of the low-concentration N− diffusion layer 203 in the high voltage transistor Tr_{NH} shown in FIGS. 11, 12, and the like is, for example, 3 to 11×10¹⁷ atoms/cm³. Meanwhile, a peak of the impurity concentration of the high-concentration N− diffusion layer 202 is, for example, 5 to 15×10¹⁷ atoms/cm³. In addition, a peak of the impurity concentration of the N+ diffusion layer 204 is, for example, 0.1 to 10×10²⁰ atoms/cm³. FIG. 15 shows one example of the relative impurity concentrations of the three regions. The b region shown in FIG. 15 is the above-described overlap region.

As shown in FIGS. 11 and 14, a width L1 of the high-concentration N− diffusion layer 202 in the Y direction is larger than a width L3 of the side wall insulating film 246 in the Y direction. A distance L2 between the high-concentration N− diffusion layer 202 and the N+ diffusion layer 204 in the Y direction is larger than the width L1 of the high-concentration N− diffusion layer 202 in the Y direction. Here, the width L1 of the high-concentration N− diffusion layer 202 in the Y direction is, for example, about 325 nm, but may be equal to or more than 250 nm and equal to or less than 450 nm. The width L3 of the side wall insulating film 246 in the Y direction is, for example, about 60 nm, but may be equal to or more than 50 nm and equal to or less than 70 nm. Further, as shown in FIG. 14, a thickness T of the gate insulating film in the Z direction is, for example, about 42 nm, but may be equal to or more than 35 nm and equal to or less than 50 nm.

For example, the high voltage transistor Tr_{NH} enters an OFF state when 20 V is applied to the drain electrode, 0 V is applied to the gate electrode, and no voltage is applied to the source electrode so that the source electrode is in an electrically floating state. While in this state, when 25 V is applied to the gate electrode, the high voltage transistor Tr_{NH} is turned on, and the voltage applied to the drain region is transferred to the source region. In addition, in the high voltage transistor Tr_{N}H, a large voltage difference occurs between the drain region and the source region at a moment of transition from an OFF state to an ON state. Therefore, an electric field in a vicinity of the drain region at a position overlapping the side wall insulating film 246 when viewed in the Z direction is intensified, and hot carriers (hot electrons) are generated by impact ionization.

In the high voltage transistor Tr_{NH}, the hot carriers generated by the impact ionization are trapped in an insulating film in a vicinity of the side wall insulating film 246 provided in the region of FIG. 13 (in the gate insulating film 241, in the liner insulating layer 247, and in the liner insulating layer 248).

In the channel region 206 of the high voltage transistor Tr_{NH}, an impurity may be introduced. For example, when a threshold voltage, which is a voltage between the gate and the source at which the high voltage transistor Tr_{NH} transitions from an OFF state to an ON state, is to be set to a positive value, a P-type impurity such as boron (B) may be introduced into the channel region 206. Meanwhile, when the threshold voltage is to be set to a negative value, an N-type impurity such as arsenic may be introduced into the channel region 206. In this way, the threshold voltage can be adjusted by introducing the P-type or N-type impurity into the channel region 206 of the high voltage transistor Tr_{NH}.

### Structure of P-Type High Voltage Transistor Tr_{PH}

FIG. 16 is a schematic cross-sectional view showing the structure of the P-type high voltage transistor Tr_{PH} shown in FIG. 10. The P-type high voltage transistor Tr_{PH} is provided in the N-type well region 311 of the semiconductor substrate 200, for example, as shown in FIG. 16. The P-type high voltage transistor Tr_{PH} includes a part of the N-type well region 311, the gate insulating film 251 such as silicon oxide (SiO₂) provided on a surface of the N-type well region 311, the gate electrode member 253 such as polycrystalline silicon (Si) provided on an upper surface of the gate insulating film 251, the gate electrode member 254 such as tungsten (W) provided on an upper surface of the gate electrode member 253, the cap insulating layer 255 such as silicon oxide (SiO₂) or silicon nitride (Si₃N₄) provided on an upper surface of the gate electrode member 254, the side wall insulating film 256 such as silicon oxide (SiO₂) or silicon nitride (Si₃N₄) provided on side surfaces of the gate electrode member 253, the gate electrode member 254, and the cap insulating layer 255 in the X direction or the Y direction. The gate electrode member 253 contains, for example, an N-type impurity such as phosphorus (P) or arsenic (As), or a P-type impurity such as boron (B). The gate electrode member 253 and the gate electrode member 254 are one of the plurality of electrodes gc described with reference to FIG. 6 and the like, and function as a gate electrode provided on the gate insulating film 251. The gate insulating film 251 is one of the plurality of insulating layers 200G described with reference to FIG. 6 and the like. A length (thickness) of the gate insulating film 251 of the P-type high voltage transistor Tr_{PH} in the Z direction is the same as a length (thickness) of the gate insulating film of the N-type high voltage transistor Tr_{NH} in the Z direction, for example, is about 42 nm, but may be equal to or more than 35 nm and equal to or less than 50 nm.

For example, as shown in FIG. 16, the P-type high voltage transistor Tr_{PH} includes the liner insulating layer 257 such as silicon oxide (SiO₂) and the liner insulating layer 258 such as silicon nitride (Si₃N₄), which are stacked on the surface of the N-type well region 311, a side surface of the gate insulating film 251 in the X direction or the Y direction, a side surface of the side wall insulating film 256 in the X direction or the Y direction, and an upper surface of the cap insulating layer 255.

The via contact electrode CS extending in the Z direction is connected to the P-type high voltage transistor Tr_{PH}. The via contact electrode CS is connected to the surface of the N− type well region 311 by penetrating the liner insulating layer 257 and the liner insulating layer 258, and functions as a source electrode or a drain electrode of the P-type high voltage transistor Tr_{PH}. The via contact electrode CS (not shown) is connected to the upper surface of the gate electrode member 244 by penetrating the liner insulating layer 258, the liner insulating layer 257, and the cap insulating layer 255. The via contact electrode CS (not shown) functions as a part of the gate electrode of the P-type high voltage transistor Tr_{PH}.

The P-type high voltage transistor Tr_{PH} has a channel region on a surface of the N− type well region 311 facing the gate electrode member 253. In other words, the channel region is a region disposed in the N-type well region 311 of the semiconductor substrate 200 and provided at a position overlapping the gate electrode when viewed in the Z direction. In addition, for example, as shown in FIG. 16, a P+ diffusion layer 213 is provided on the surface of the N-type well region 311. In FIG. 16, the P+ diffusion layer 213 on a left side functions as a source region, and the P+ diffusion layer 213 on a right side functions as a drain region.

The P+ diffusion layer 213 is a diffusion layer region, which is provided in the N− type well region 311 of the semiconductor substrate 200, connected to the via contact electrode CS extending in the Z direction, and containing a second conductive-type impurity. The second conductive-type impurity is, for example, a P-type impurity such as boron (B).

The P-type high voltage transistor Tr_{PH} does not include a diffusion layer corresponding to the high-concentration N− diffusion layer 202, unlike the high voltage transistor Tr_{NH}.

### Structure of N-Type Low Voltage Transistor Tr_{NL}

FIG. 17 is a schematic cross-sectional view showing the structure of the N-type low voltage transistor Tr_{NL} shown in FIG. 10. The N-type low voltage transistor Tr_{NL} is provided in the P-type well region 310 of the semiconductor substrate 200, for example, as shown in FIG. 17. The N-type low voltage transistor Tr_{NL} includes a part of the P-type well region 310, a gate insulating film 341 such as silicon oxide (SiO₂) provided on a surface of the P-type well region 310, a gate electrode member 343 such as polycrystalline silicon (Si) provided on an upper surface of the gate insulating film 341, a gate electrode member 344 such as tungsten (W) provided on an upper surface of the gate electrode member 343, a cap insulating layer 345 such as silicon oxide (SiO₂) or silicon nitride (Si₃N₄) provided on an upper surface of the gate electrode member 344, and a side wall insulating film 346 such as silicon oxide (SiO₂) or silicon nitride (Si₃N₄) provided on side surfaces of the gate electrode member 343, the gate electrode member 344, and the cap insulating layer 345 in the X direction or the Y direction. The gate electrode member 343 contains, for example, an N-type impurity such as phosphorus (P) or arsenic (As), or a P-type impurity such as boron (B). In addition, the gate electrode member 343 and the gate electrode member 344 are one of the plurality of electrodes gc described with reference to FIG. 6 and the like, and function as the gate electrode provided on the gate insulating film 341. The gate insulating film 341 is one of the plurality of insulating layers 200G described with reference to FIG. 6 and the like. A length (thickness) of the gate insulating film 341 of the N-type low voltage transistor Tr_{NL} in the Z direction is shorter than a length (thickness) of the gate insulating film of the N-type high voltage transistor Tr_{NH} in the Z direction, and may be, for example, equal to or longer than 6 nm and equal to or shorter than 8 nm.

The N-type low voltage transistor Tr_{NL} includes a liner insulating layer 347 such as silicon oxide (SiO₂) and a liner insulating layer 348 such as silicon nitride (Si₃N₄), which are stacked on the surface of the P-type well region 310, a side surface of the gate insulating film 341 in the X direction or the Y direction, a side surface of the side wall insulating film 346 in the X direction or the Y direction, and an upper surface of the cap insulating layer 345.

The via contact electrode CS extending in the Z direction is connected to the N− type low voltage transistor Tr_{NL}. The via contact electrode CS is connected to the surface of the P-type well region 310 by penetrating the liner insulating layer 347 and the liner insulating layer 348, and functions as a source electrode or a drain electrode of the N-type low voltage transistor Tr_{NL}. The via contact electrode CS (not shown) penetrates the liner insulating layer 348, the liner insulating layer 347, and the cap insulating layer 345 and is connected to the upper surface of the gate electrode member 344. The via contact electrode CS (not shown) functions as a part of the gate electrode of the N-type low voltage transistor Tr_{NL}.

In addition, the N-type low voltage transistor Tr_{NL} has a channel region on a surface of the P-type well region 310 facing the gate electrode member 343. In other words, the channel region is a region disposed in the P-type well region 310 of the semiconductor substrate 200 and provided at a position overlapping the gate electrode when viewed in the Z direction. In addition, for example, as shown in FIGS. 10 and 17, an N+ diffusion layer 303 is provided on the surface of the P-type well region 310. In FIG. 17, the N+ diffusion layer 303 on a left side functions as a source region, and the N+ diffusion layer 303 on a right side functions as a drain region.

The N+ diffusion layer 303 is a diffusion layer region, which is provided in the P-type well region 310 of the semiconductor substrate 200, connected to the via contact electrode CS extending in the Z direction, and containing the first conductive-type impurity. A distance from the channel region to the via contact electrode CS of the N-type low voltage transistor Tr_{NL} is shorter than a distance from the channel region 206 to the via contact electrode CS of the N-type high voltage transistor Tr_{NH}.

The N-type low voltage transistor Tr_{NL} does not include a diffusion layer corresponding to the high-concentration N− diffusion layer 202, unlike the high voltage transistor Tr_{NH}.

### Structure of P-Type Low Voltage Transistor Tr_{PL}

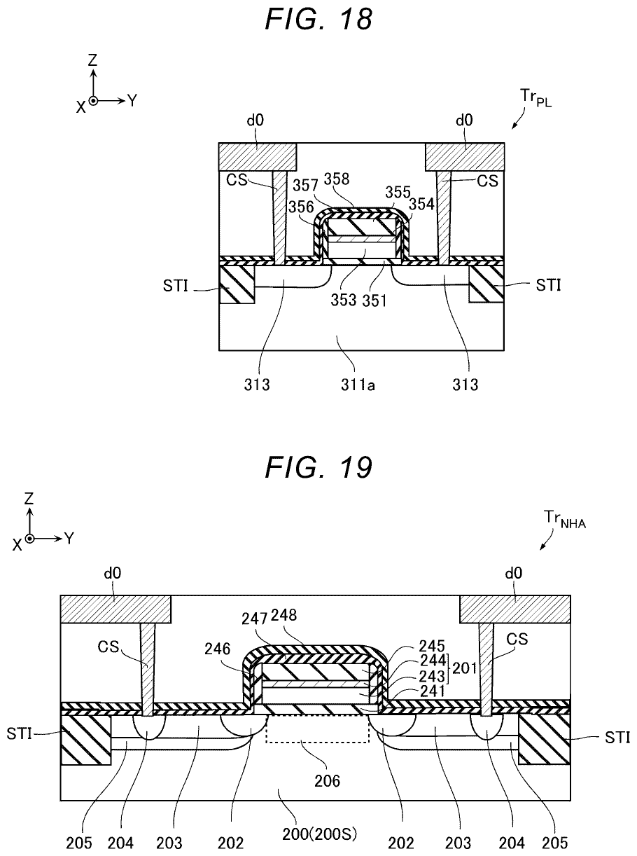

FIG. 18 is a schematic cross-sectional view showing the structure of the P-type low voltage transistor Tr_{PL} shown in FIG. 10. The P-type low voltage transistor Tr_{PL} is provided in the N-type well region 311a of the semiconductor substrate 200, for example, as shown in FIG. 18. The P-type low voltage transistor Tr_{PL} includes a part of the N-type well region 311a, a gate insulating film 351 such as silicon oxide (SiO₂) provided on a surface of the N-type well region 311a, a gate electrode member 353 such as polycrystalline silicon (Si) provided on an upper surface of the gate insulating film 351, a gate electrode member 354 such as tungsten (W) provided on an upper surface of the gate electrode member 353, a cap insulating layer 355 such as silicon oxide (SiO₂) or silicon nitride (Si₃N₄) provided on an upper surface of the gate electrode member 354, a side wall insulating film 356 such as silicon oxide (SiO₂) or silicon nitride (Si₃N₄) provided on side surfaces of the gate electrode member 353, the gate electrode member 354, and the cap insulating layer 355 in the X direction or the Y direction. The gate electrode member 353 contains, for example, an N-type impurity such as phosphorus (P) or arsenic (As), or a P-type impurity such as boron (B). The gate electrode member 353 and the gate electrode member 354 are one of the plurality of electrodes gc described with reference to FIG. 6 and the like, and function as the gate electrode provided on the gate insulating film 351. The gate insulating film 351 is one of the plurality of insulating layers 200G described with reference to FIG. 6 and the like. A length (thickness) of the gate insulating film 351 of the P-type low voltage transistor Tr_{PL} in the Z direction is shorter than a length (thickness) of the gate insulating film of the N-type high voltage transistor Tr_{NH} in the Z direction, and may be, for example, equal to or longer than 6 nm and equal to or shorter than 8 nm.

The P-type low voltage transistor Tr_{PL} includes a liner insulating layer 357 such as silicon oxide (SiO₂) and a liner insulating layer 358 such as silicon nitride (Si₃N₄), which are stacked on the surface of the N-type well region 311a, a side surface of the gate insulating film 351 in the X direction or the Y direction, a side surface of the side wall insulating film 356 in the X direction or the Y direction, and an upper surface of the cap insulating layer 355.

The via contact electrode CS extending in the Z direction is connected to the P-type low voltage transistor Tr_{PL}. The via contact electrode CS is connected to the surface of the N-type well region 311a by penetrating the liner insulating layer 357 and the liner insulating layer 358, and functions as a source electrode or a drain electrode of the P-type low voltage transistor Tr_{PL}. The via contact electrode CS (not shown) penetrates the liner insulating layer 358, the liner insulating layer 357, and the cap insulating layer 355 and is connected to the upper surface of the gate electrode member 354. The via contact electrode CS (not shown) functions as a part of the gate electrode of the P-type low voltage transistor Tr_{PL}.

The P-type low voltage transistor Tr_{PL} has a channel region on a surface of the N− type well region 311a facing the gate electrode member 353. In other words, the channel region is a region disposed in the N-type well region 311a of the semiconductor substrate 200 and provided at a position overlapping the gate electrode when viewed in the Z direction. In addition, for example, as shown in FIGS. 10 and 18, a P+ diffusion layer 313 is provided on the surface of the N-type well region 311a. In FIG. 18, the P+ diffusion layer 313 on a left side functions as a source region, and the P+ diffusion layer 313 on a right side functions as a drain region.

The P+ diffusion layer 313 is a diffusion layer region, which is provided in the N− type well region 311a of the semiconductor substrate 200, connected to the via contact electrode CS extending in the Z direction, and containing the second conductive-type impurity. A distance from the channel region to the via contact electrode CS of the P-type low voltage transistor Tr_{PL} is shorter than a distance from the channel region 206 to the via contact electrode CS of the N-type high voltage transistor Tr_{NH}.

The P-type low voltage transistor Tr_{PL} does not include a diffusion layer corresponding to the high-concentration N− diffusion layer 202, unlike the high voltage transistor Tr_{NH}.

### Effect of First Embodiment

In the high voltage transistor Tr_{NH} described with reference to FIG. 12 and the like, when the high-concentration N− diffusion layer 202 is not provided, an upper surface side of the low-concentration N− diffusion layer 203 in the Z direction is easily depleted. That is, electrons are easily trapped by the liner insulating layer 248 such as silicon nitride (Si₃N₄), and even more so at a position overlapping the high-concentration N− diffusion layer 202 when viewed in the Z direction, where the hot carriers are generated by impact ionization. Therefore, a position where the low-concentration N− diffusion layer 203 is provided on the surface of the semiconductor substrate 200 is easily depleted. As a result, a current may be reduced, which is flowing into the high voltage transistor Tr_{NH} when the high voltage transistor Tr_{NH} is set to an ON state.

Therefore, when the high-concentration N− diffusion layer 202 is not provided in the high voltage transistor Tr_{NH} shown in FIG. 12 and the like and the impurity concentration of the low-concentration N− diffusion layer 203 is uniformly increased, a problem occurs, in that a breakdown voltage when a high voltage is applied to the drain region decreases. With reference to FIG. 13, when 0 V is applied to the gate electrode of the high voltage transistor Tr_{NH} and a high voltage is applied to the drain electrode, a high voltage is applied to the N+ diffusion layer 204 of the drain region (right side in FIG. 13). At this time, since regions of the N+ diffusion layer 204 and the low-concentration N− diffusion layer 203 in the Y direction can be simulated as a series resistor connecting a node n1 and a node n2, and a voltage drop occurs, a voltage of the node n2 when the electron is used as a reference is higher than a voltage of the node n1 when the electron is used as a reference. When the impurity concentration of the low-concentration N− diffusion layer 203 is uniformly increased, the voltage drop at the node n2 is reduced, and a voltage difference between the source and the drain is concentrated in the channel region 206. Therefore, a breakdown voltage of the high voltage transistor Tr_{NH} decreases.

Meanwhile, for example, as shown in FIG. 13 and the like, the high voltage transistor Tr_{NH} according to the present embodiment has the high-concentration N− diffusion layer 202 at the node n1. As a result, since the impurity concentration of the low-concentration N− diffusion layer 203 is maintained, and the voltage of the node n2 is maintained, a decrease in the breakdown voltage of the high voltage transistor Tr_{NH} can be avoided or reduced. In addition, in the high voltage transistor Tr_{NH} according to the present embodiment, an impurity concentration at the node n2 can be increased by providing the high-concentration N− diffusion layer 202. As a result, even when the hot carriers are trapped in the liner insulating layer 248 and the like, the current flowing into the high voltage transistor Tr_{NH} when the high voltage transistor Tr_{NH} is set to an ON state can be prevented from being decreased.

In the high voltage transistor Tr_{NH}, a location where the impact ionization occurs is a location near a position separated from the edge of the gate electrode 201 or channel region 206 in the channel direction (for example, Y direction) by about 250 nm. In the present embodiment, the high-concentration N− diffusion layer 202 is provided in a region including the position separated by about 250 nm from the edge of the gate electrode 201.

### Modification Example of First Embodiment

FIG. 19 is a schematic cross-sectional view showing the structure of the N-type high voltage transistor Tr_{NHA} according to the modification example of the first embodiment. The same configurations as those in FIG. 12 are denoted by the same reference numerals, and redundant description will not be shown.

As shown in FIG. 19, the N-type high voltage transistor Tr_{NHA} according to the modification example of the first embodiment is different as compared to the N-type high voltage transistor Tr_{NH} according to the first embodiment shown in FIG. 12 and the like in a point in that the P− diffusion layer 205 is further provided.

The P− diffusion layer 205 is a diffusion layer provided at a position overlapping the source region and the drain region when viewed in the Z direction, and between the channel region 206 and the insulating region STI, and contains a P-type impurity such as boron (B).

The P− diffusion layer 205 can reduce a leakage current between the source region and the drain region of the N-type high voltage transistor Tr_{NHA} of the modification example, and can reduce a leakage current between the N-type high voltage transistor Tr_{NHA} of the modification example and the other transistors adjacent to the N-type high voltage transistor Tr_{NHA}.

### Method of Manufacturing N-Type High Voltage Transistor Tr_{NH} and the Like According to First Embodiment

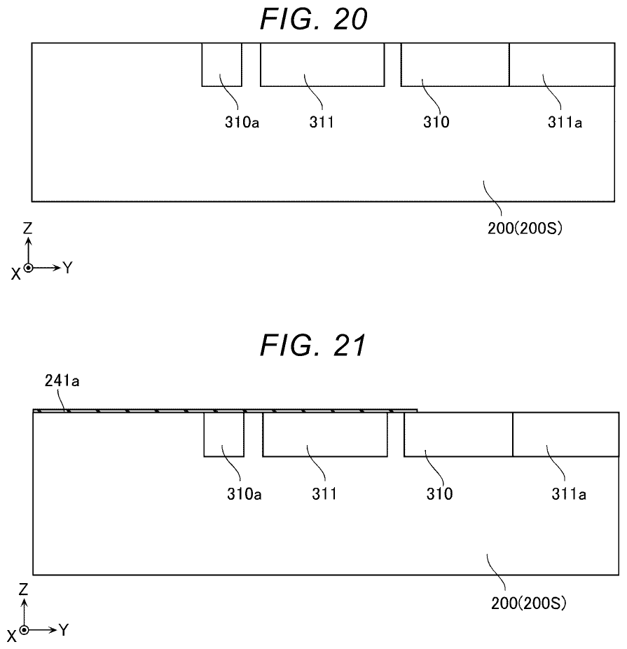

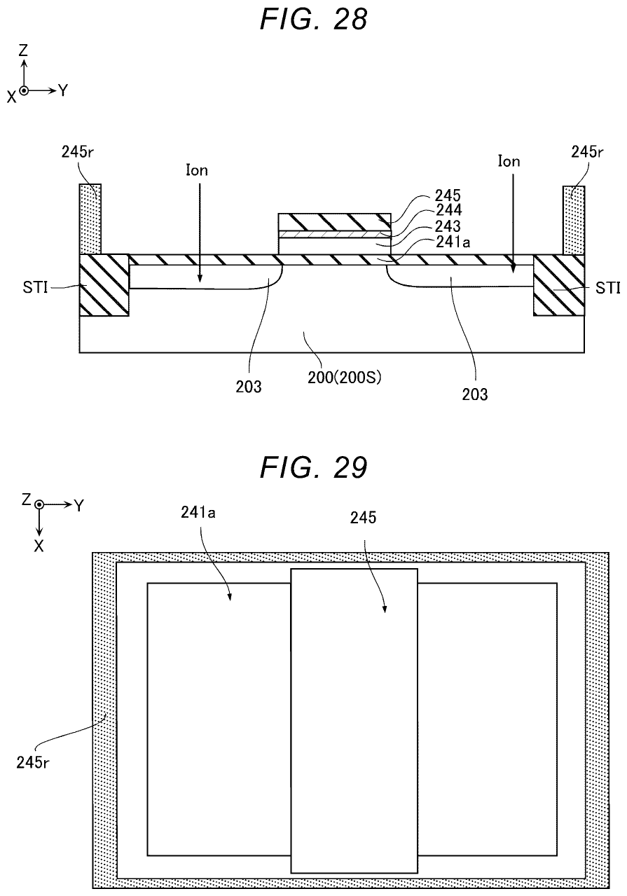

Next, a method of manufacturing an N-type high voltage transistor Tr_{NH} and the like according to the first embodiment will be described with reference to FIGS. 20 to 37. FIGS. 20 to 27 are schematic cross-sectional views showing the same manufacturing method, and show a cross section corresponding to FIG. 10. FIGS. 28, 30, 32, 33, 35, and 36 are schematic cross-sectional views showing the same manufacturing method, and show cross sections corresponding to FIG. 12. FIGS. 29, 31, and 34 are schematic plan views showing the same manufacturing method, and show planes corresponding to FIG. 11. FIG. 37 is a schematic cross-sectional view showing the same manufacturing method, and shows a cross section corresponding to FIG. 17.

First, as shown in FIG. 20, a P-type impurity such as boron (B) and an N-type impurity such as phosphorus (P) are implanted into the surface of the semiconductor substrate 200 to form P-type well regions 310a and 310 and N-type well regions 311a and 311. This step is performed by, for example, ion implantation and the like. Specifically, a resist in which a region corresponding to the P-type well regions 310a and 310 is opened is formed on the surface of the semiconductor substrate 200, and a P-type impurity such as boron (B) is introduced into the semiconductor substrate 200 by, for example, ion implantation. After the resist in which the region corresponding to the P-type well regions 310a and 310 is opened is peeled off, a resist in which a region corresponding to the N-type well regions 311a and 311 is opened is formed, and an N-type impurity such as phosphorus (P) is introduced into the semiconductor substrate 200 by, for example, ion implantation. Thereafter, the resist in which the region corresponding to the N-type well regions 311a and 311 is opened is peeled off. In this manner, the P-type well regions 310a and 310 and the N-type well regions 311a and 311 are formed. In order to adjust a threshold voltage of the N-type high voltage transistor Tr_{NH}, a P-type impurity or an N-type impurity may be introduced into a region corresponding to the channel region 206 in the semiconductor substrate 200.

Next, for example, as shown in FIG. 21, an insulating film 241a such as silicon oxide is formed on the upper surface of the semiconductor substrate 200. This step is performed by, for example, thermal oxidation and the like. The insulating film 241a is formed with a thickness thinner than a thickness of the gate insulating film 241 (FIG. 12) in the Z direction. Next, a part of the insulating film 241a is removed. This step is performed by, for example, wet etching and the like. In this step, the insulating film 241a remains in a region corresponding to the high voltage transistors Tr_{NH} and Tr_{PH}, and the insulating film 241a is removed in a region corresponding to the low voltage transistors Tr_{NL} and Tr_{PL}.

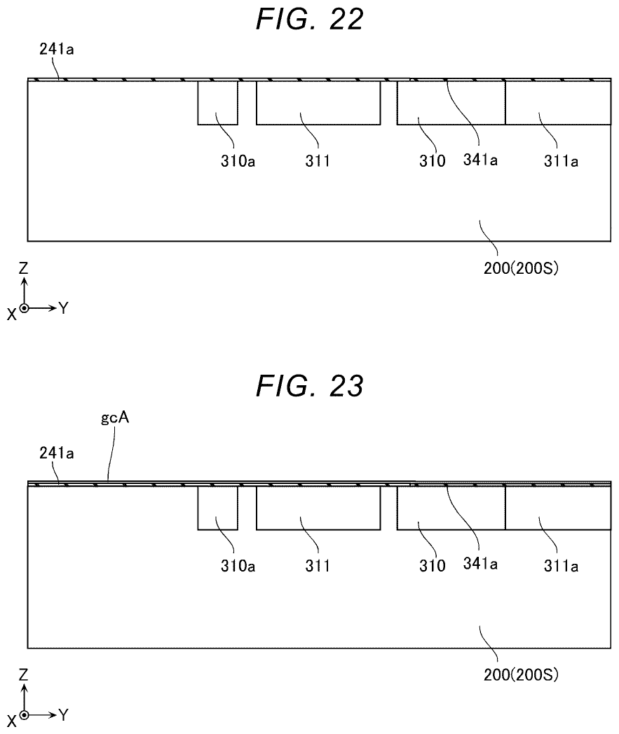

Next, for example, as shown in FIG. 22, an insulating film 341a such as silicon oxide is formed. This step is performed by, for example, thermal oxidation and the like. The insulating film 341a is formed with the same thickness as a thickness of the gate insulating film 341 (FIG. 17) in the Z direction. In this step, the thickness of the insulating film 341a is increased in the region corresponding to the high voltage transistors Tr_{NH} and Tr_{PH}, so that the insulating film 341a has the same thickness as the thickness of the gate insulating film 241 (FIG. 12) in the Z direction.

Next, for example, as shown in FIG. 23, a conductive layer gcA of polycrystalline silicon (Si) is formed. This step is performed by, for example, CVD.

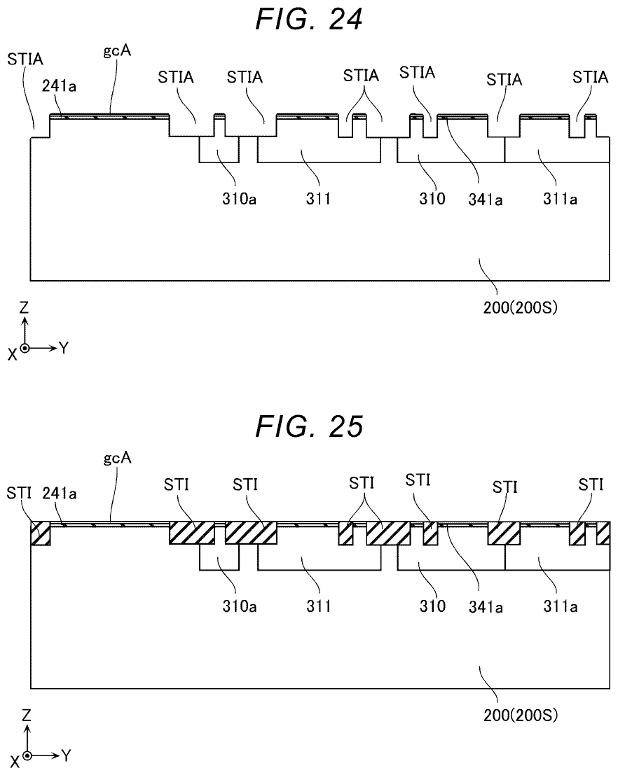

Next, for example, as shown in FIG. 24, an opening STIA is formed at a position corresponding to the insulating region STI (FIG. 10). In this step, for example, the conductive layer gcA and insulating films 241a and 341a at the position corresponding to the insulating region STI are removed, and the semiconductor substrate 200 is anisotropically etched to a depth of, for example, 0.4 μm in the Z direction. The opening STIA extends in the Z direction and the X direction or the Y direction, penetrates the conductive layer gcA and the insulating films 241a and 341a, and divides a part of the surface of the semiconductor substrate 200. This step is performed by, for example, a method such as reactive ion etching (RIE).

Next, for example, as shown in FIG. 25, the insulating region STI is formed on the semiconductor substrate 200. This step is performed by, for example, CVD. In this step, the opening STIA is embedded with an insulating layer. Next, a part of the formed insulating layer is removed to form a plurality of insulating regions STI, for example, as shown in FIG. 25. The step of removing the part of the formed insulating layer is performed by, for example, a method such as chemical mechanical polishing (CMP).

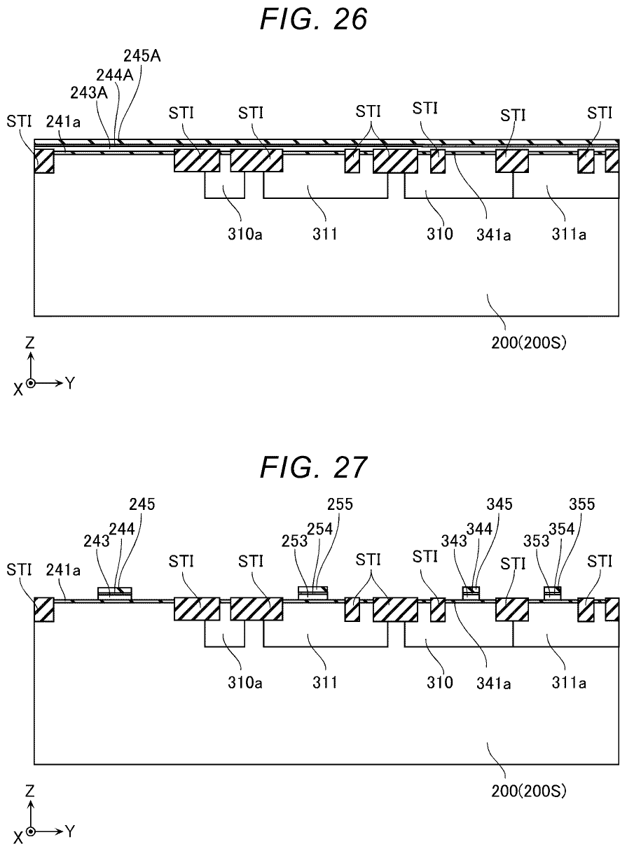

Next, for example, as shown in FIG. 26, a gate electrode member 243A such as polycrystalline silicon (Si), a gate electrode member 244A such as tungsten (W), and a cap insulating layer 245A such as silicon oxide (SiO₂) or silicon nitride (Si₃N₄) are sequentially stacked on an upper surface of the conductive layer gcA. This step is performed by, for example, CVD.

Next, for example, as shown in FIG. 27, the gate electrode member 243A, the gate electrode member 244A, and the cap insulating layer 245A are removed in a region other than the region serving as the gate electrode. This step is performed by, for example, a method such as RIE. In this manner, the gate electrode member 243, the gate electrode member 244, and the cap insulating layer 245 of the high voltage transistor Tr_{NH}, the gate electrode member 253, the gate electrode member 254, and the cap insulating layer 245 of the high voltage transistor Tr_{PH}, the gate electrode member 343, the gate electrode member 344, and the cap insulating layer 345 of the low voltage transistor Tr_{NL}, and the gate electrode member 353, the gate electrode member 354, and the cap insulating layer 355 of the low voltage transistor Tr_{PL} are formed.

Next, for example, as shown in FIGS. 28 and 29, a resist 245r in which a region corresponding to the entire high voltage transistor Tr_{NH} is opened is formed, and the low-concentration N− diffusion layer 203 is formed by, for example, ion-implanting phosphorus (P). For example, phosphorus (P) may be ion-implanted at a dose amount of 5.3×10¹² atoms/cm².

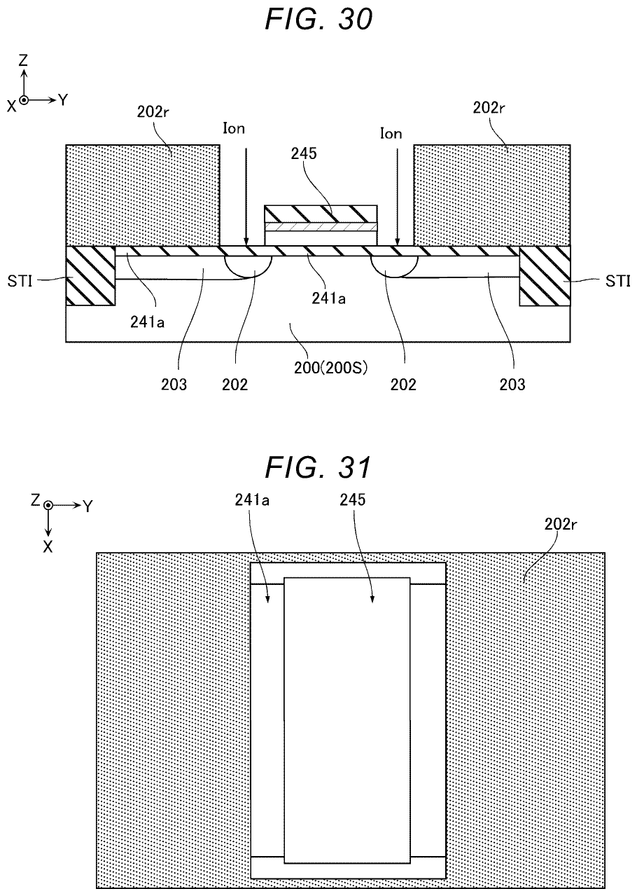

Next, for example, as shown in FIGS. 30 and 31, a resist 202r in which a region corresponding to the high-concentration N− diffusion layer 202 and the cap insulating layer 245 is opened is formed, and for example, phosphorus (P) is ion-implanted. For example, phosphorus (P) may be ion-implanted at a dose amount of 1.0×10¹² atoms/cm². As a result, since phosphorus (P) can be ion-implanted into a region (region between resist 202r and cap insulating layer 245 in FIG. 30) corresponding to the high-concentration N− diffusion layer 202 in the semiconductor substrate 200 at a total dose amount of, for example, 6.3×10¹² atoms/cm², the high-concentration N− diffusion layer 202 is formed.

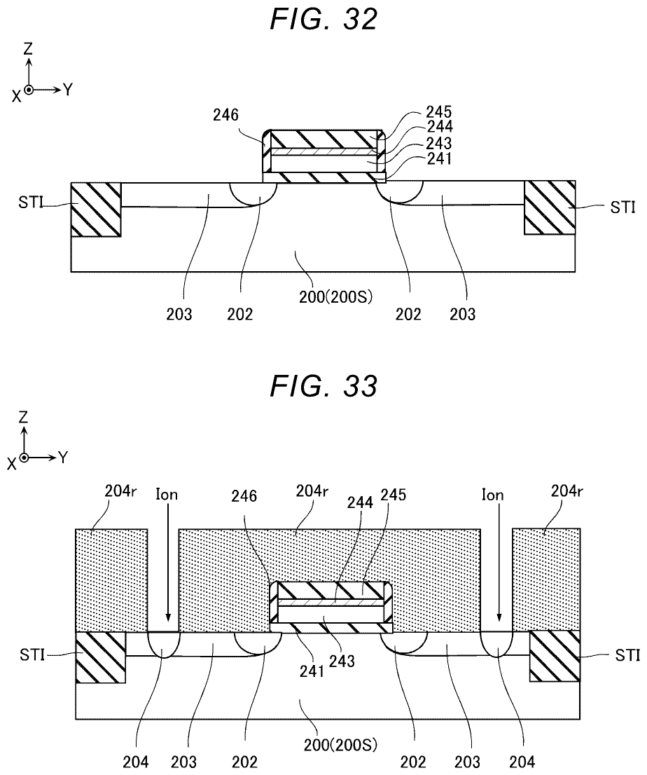

Next, for example, as shown in FIG. 32, after the resist 202r is peeled off, the silicon oxide (SiO₂) or the silicon nitride (Si₃N₄) is deposited on the upper surface of the semiconductor substrate 200, the cap insulating layer 245, and the side surfaces of the gate electrode member 243, the gate electrode member 244, and the cap insulating layer 245 in the X direction or the Y direction, and the anisotropic etching is performed to form the side wall insulating film 246. At this time, the gate insulating film 241 is formed by simultaneously removing the insulating film 241a in the source region and the drain region (active region). By removing the insulating film 241a by anisotropic etching, the gate insulating film 241 is formed without protruding from an end portion of the side wall insulating film 256 when viewed in the Z direction. As a result, a bonding depth of the N+ diffusion layer 204 in the Z direction, which will be described later, can be made shallow.

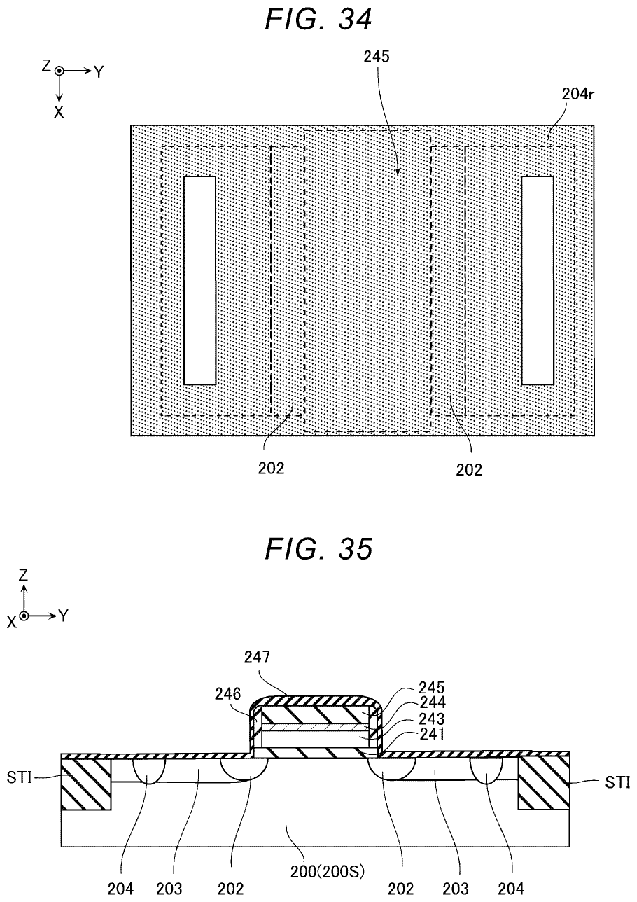

Next, for example, as shown in FIGS. 33 and 34, a resist 204r in which a region corresponding to the N+ diffusion layer 204 is opened is formed, and the N+ diffusion layer 204 is formed by, for example, ion-implanting arsenic (As).

Next, for example, as shown in FIG. 35, after the resist 204r is peeled off, a liner insulating layer 247 such as silicon oxide (SiO₂) is formed on the surface of the semiconductor substrate 200, the side surface of the gate insulating film 241 in the X direction or the Y direction, the side surface of the side wall insulating film 246 in the X direction or the Y direction, and the upper surface of the cap insulating layer 245. This step is performed by, for example, CVD.

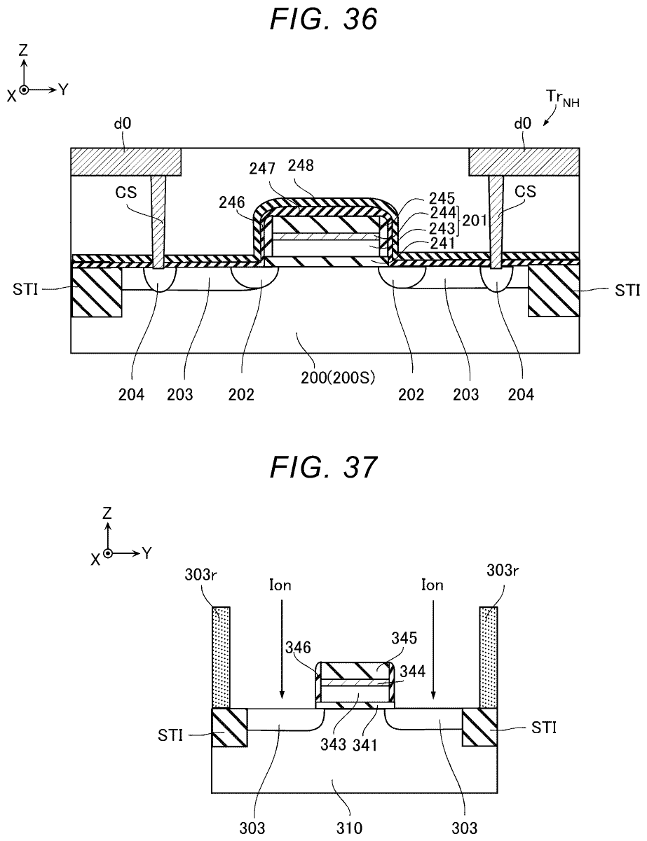

Next, for example, as shown in FIG. 36, the high voltage transistor Tr_{NH} is formed by forming the liner insulating layer 248 and the via contact electrode CS such as silicon nitride (Si₃N₄).

For example, when the resist 204r in which the region corresponding to the N+ diffusion layer 204 is opened is formed, which is described with reference to FIGS. 33 and 34, at the same time, for example, as shown in FIG. 37, a resist 303r in which a region corresponding to the entire low voltage transistor Tr_{NL} is opened is formed on an upper surface of the P-type well region 310 when viewed in the Z direction. For example, the N+ diffusion layer 303 is formed by ion-implanting arsenic (As).

The N-type low voltage transistor Tr_{NL} improves speed performance by shortening a gate length to increase a current driving force. Therefore, it is important to maintain a short channel effect resistance. When the thickness of the insulating film 341a in the Z direction is large when the arsenic (As) is ion-implanted, it is necessary to increase an energy of the ion implantation. In this situation, a bonding depth of the N+ diffusion layer 303 in the Z direction becomes deep, and the short channel effect resistance of the N-type low voltage transistor Tr_{NL} deteriorates. Meanwhile, when the insulating film 341a is removed when the arsenic (As) is ion-implanted, the energy of the ion implantation can be reduced. In this situation, since the bonding depth of the N+ diffusion layer 303 in the Z direction can be made shallow, the short channel effect resistance of the N-type low voltage transistor Tr_{NL} can be improved.

In the present embodiment, although not shown, for example, when the side wall insulating film 346 is formed by the same step as a step described with reference to FIG. 32, the insulating film 341a is simultaneously removed by anisotropic etching, and the gate insulating film 341 is formed without protruding from an end portion of the side wall insulating film 346 when viewed in the Z direction. As a result, the bonding depth of the N+ diffusion layer 303 in the Z direction can be made shallow. That is, the short channel effect resistance can be improved, of which the N-type low voltage transistor Tr_{NL} is formed on the same semiconductor substrate 200 as that of the N-type high voltage transistor Tr_{NH}, without increasing the number of manufacturing steps.

Although not shown, after the N+ diffusion layer 204 and the N+ diffusion layer 303 are formed in steps shown in FIGS. 33 and 34, a resist in which a region corresponding to the P+ diffusion layer 213 described with reference to FIG. 16 and the P+ diffusion layer 313 described with reference to FIG. 18 are opened is formed, and the P+ diffusion layer 213 and the P+ diffusion layer 313 are simultaneously formed by, for example, ion-implanting boron (B). In addition, since the insulating film 341a is removed when the boron (B) is ion-implanted, the energy of the ion implantation can be reduced, and the bonding depth of the P+ diffusion layer 213 and the P+ diffusion layer 313 in the Z direction can be made shallow.

### Method of Manufacturing N-Type High Voltage Transistor Tr_{NHA} and the Like According to Modification Example of First Embodiment

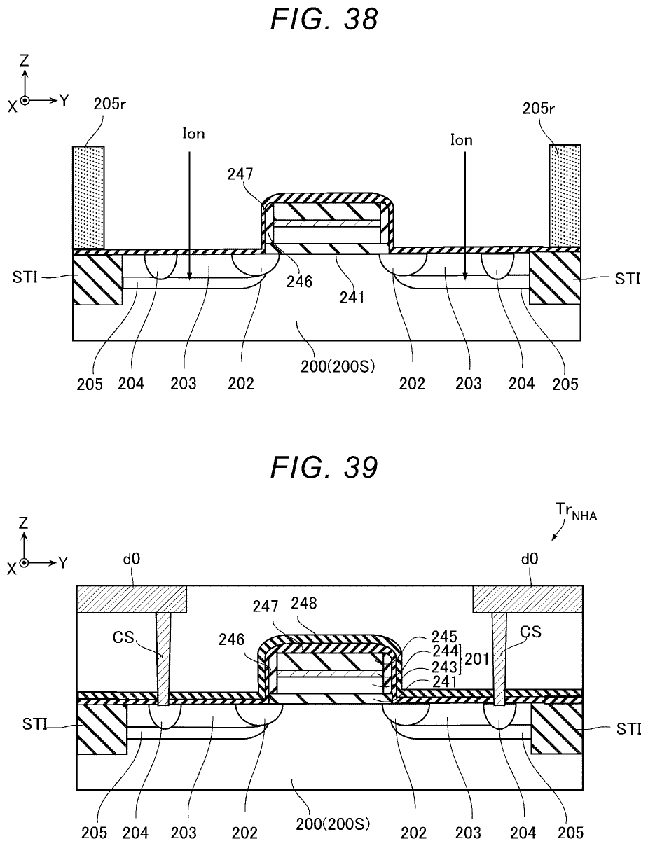

Next, a method of manufacturing the N-type high voltage transistor Tr_{NHA} according to the modification example of the first embodiment will be described with reference to FIGS. 38 and 39. FIGS. 38 and 39 are schematic cross-sectional views showing the method of manufacturing the N-type high voltage transistor Tr_{NHA} according to the modification example of the first embodiment, and show cross sections corresponding to FIG. 19.

The high voltage transistor Tr_{NHA} is basically manufactured in the same manner as that in the high voltage transistor Tr_{NH}.

Meanwhile, for example, after the liner insulating layer 247 is formed as described with reference to FIG. 35, a resist 205r in which the entire high voltage transistor Tr_{NH} is opened may be formed. For example, as shown in FIG. 38, the P− diffusion layer 205 may be formed by, for example, ion-implanting boron (B) into a region deeper in the Z direction than regions of the high-concentration N− diffusion layer 202 and the low-concentration N− diffusion layer 203.

Thereafter, for example, as shown in FIG. 39, the liner insulating layer 248 and the via contact electrode CS such as silicon nitride (Si₃N₄) are formed, so that the high voltage transistor Tr_{NHA} is formed.

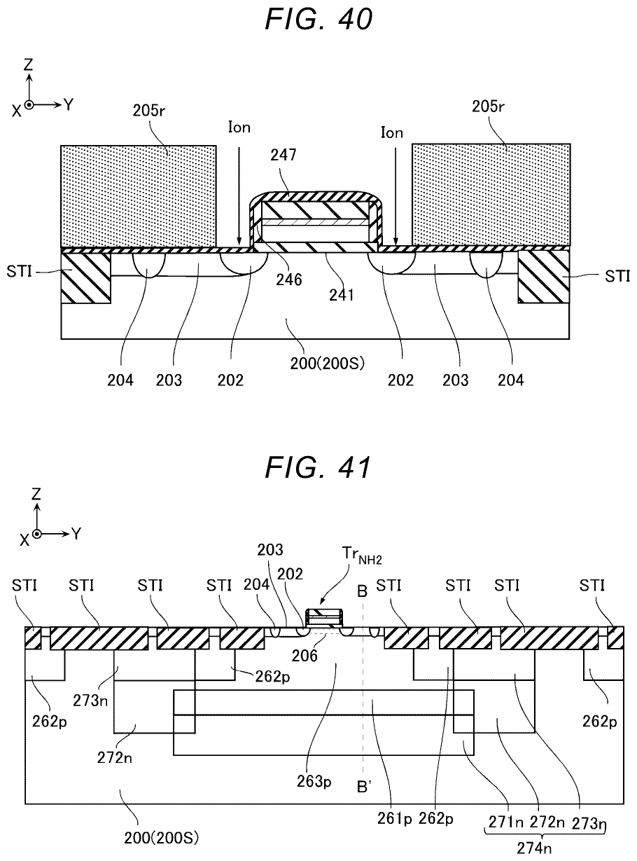

As described with reference to FIGS. 30 and 31, when the high-concentration N− diffusion layer 202 is formed, an effective gate length of the high voltage transistor Tr_{NH} may be reduced. Therefore, for example, after the liner insulating layer 247 is formed as described with reference to FIG. 35, for example, as shown in FIG. 40, the resist 205r in which a region corresponding to the high-concentration N− diffusion layer 202 and the cap insulating layer 245 is opened may be formed, and for example, phosphorus (P) may be ion-implanted. As a result, not only an upper side of the high-concentration N− diffusion layer 202 can be prevented from being depleted in the Z direction by the hot carriers, but also the effective gate length of the high voltage transistor Tr_{NH} can be prevented from being shortened.

### Second Embodiment

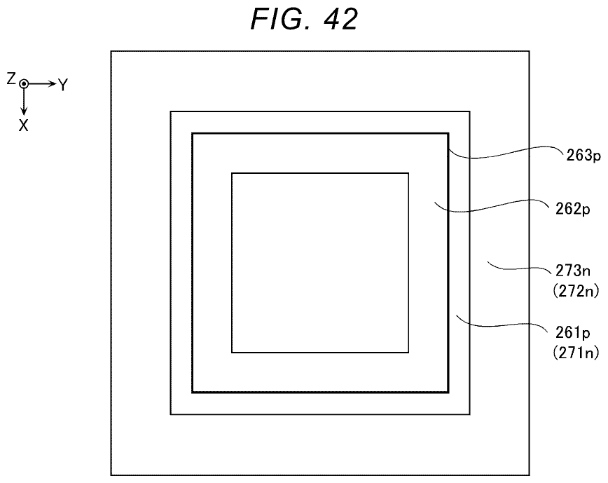

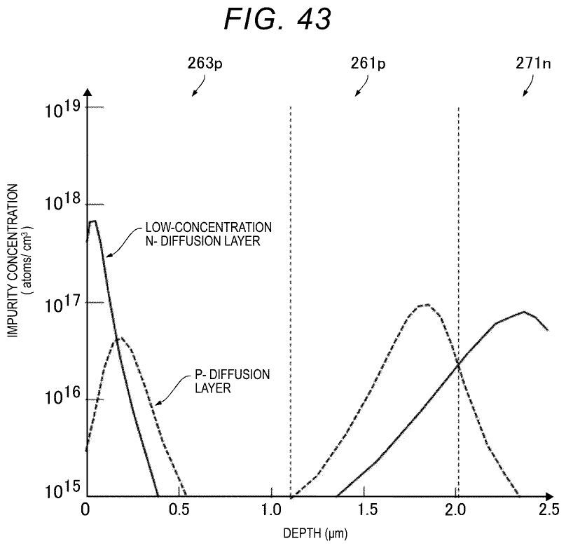

Next, an N-type high voltage transistor Tr_{NH2} according to a second embodiment will be described with reference to FIGS. 41, 42, and the like. FIG. 41 is a schematic cross-sectional view showing a structure of the N-type high voltage transistor Tr_{NH2} according to the second embodiment. FIG. 42 is a schematic plan view showing a well formation region in which the N− type high voltage transistor Tr_{NH2} according to the second embodiment is configured. The same configurations as those in FIG. 12 and the like are denoted by the same reference numerals, and redundant description will not be shown.

The high voltage transistor Tr_{NH} according to the first embodiment is provided in the semiconductor substrate region 200S as described with reference to FIGS. 11 to 14 and the like. The N-type high voltage transistor Tr_{NHA} according to the modification example of the first embodiment is also provided in the semiconductor substrate region 200S in the same manner. Meanwhile, such a configuration is merely an example, and the N-type high voltage transistor Tr_{NH} or the N-type high voltage transistor Tr_{NHA} may be provided in a region other than the semiconductor substrate region 200S.

For example, a peripheral circuit PC of a semiconductor memory device according to the second embodiment is basically configured in the same manner as that of the peripheral circuit PC of the semiconductor memory device according to the first embodiment. However, the peripheral circuit PC of the semiconductor memory device according to the second embodiment includes a plurality of N-type high voltage transistors Tr_{NH2} (FIG. 41) instead of the plurality of N− type high voltage transistors Tr_{NH} (FIG. 12 and the like) or a plurality of N-type high voltage transistors Tr_{NHA} (FIG. 19 and the like).

The N-type high voltage transistor Tr_{NH2} (FIG. 41) according to the second embodiment is basically configured in the same manner as that of the N-type high voltage transistor Tr_{NH} (FIG. 12 and the like) or the N-type high voltage transistor Tr_{NHA} (FIG. 19 and the like) according to the first embodiment. However, the N-type high voltage transistor Tr_{NH2} according to the second embodiment is provided in a P-type well region 263p instead of the semiconductor substrate region 200S. In addition, the P-type well region 263p provided with the high voltage transistor Tr_{NH2} is electrically separated from the semiconductor substrate region 200S with an N-type well region 274n interposed therebetween. Hereinafter, a well region in which the N-type high voltage transistor Tr_{NH2} according to the present embodiment is provided will be specifically described with reference to FIGS. 41 and 42.

The channel region 206, the N+ diffusion layer 204, the high-concentration N− diffusion layer 202, and the low-concentration N− diffusion layer 203 of the N-type high voltage transistor Tr_{NH2} are provided in the P-type well region 263p. As described above, the N-type well region 274n for separation, which is used for electrically separating the P-type well region 263p from the semiconductor substrate region 200S is provided in the semiconductor substrate 200. The P-type well region 263p can be applied with a negative bias because the P-type well region 263p is electrically separated from the semiconductor substrate region 200S.

The N-type well region 274n for separation is configured with three regions of an N-type well region 271n, an N-type well region 272n, and an N-type well region 273n. In addition, a P-type well region 261p and a P-type well region 262p are provided in a region surrounded by the N-type well region 274n for separation in addition to the P-type well region 263p on the semiconductor substrate 200.

The P-type well region 261p is provided below the P-type well region 263p. The P-type well region 262p surrounds a side surface (XY direction) of the P-type well region 263p when viewed in the Z direction.

The N-type well region 271n is provided below the P-type well region 261p. The N-type well region 272n surrounds the P-type well region 261p when viewed in the Z direction, and is connected to the N-type well region 271n and the N-type well region 273n. The N-type well region 273n surrounds the P-type well region 262p when viewed in the Z direction.

FIG. 43 is a diagram conceptually showing an impurity concentration of the N-type high voltage transistor Tr_{NH2} in the depth direction (Z direction) along a dotted line of B-B′ of FIG. 41. The impurity concentration shown in FIG. 43 is an impurity concentration when the P− diffusion layer 205 (not shown) is provided in the high voltage transistor Tr_{NH2} shown in FIG. 41.

As shown in FIG. 41, the low-concentration N− diffusion layer 203 is provided on a surface of the P-type well region 263p, and the P− diffusion layer 205 (not shown) is provided below the low-concentration N− diffusion layer 203. Therefore, in an example shown in FIG. 43, a solid line having a peak near the surface of the P-type well region 263p indicates the impurity concentration of the low-concentration N− diffusion layer 203, and the peak of the impurity concentration is, for example, 3 to 11×10¹⁷ atoms/cm³. In addition, the dotted line indicating a peak near the surface of the P-type well region 263p at a depth of 0.2 μm indicates an impurity concentration of the P− diffusion layer 205. In a region at a depth from the surface of the P-type well region 263p of about 0.5 μm to about 1.1 μm, a P-type impurity concentration is, for example, equal to or less than 10¹⁵ atoms/cm³, which is the same as that of the semiconductor substrate region 200S.

In the example shown in FIG. 43, in a region at a depth from the surface of the P− type well region 263p of about 1.1 μm to about 1.8 μm, an impurity concentration of a P-type impurity monotonically increases, and in a region at a depth from about 1.8 μm to about 2.4 μm, the impurity concentration of the P-type impurity monotonically decreases. In addition, in a region at a depth from the surface of the P-type well region 263p of about 1.4 μm to about 2.4 μm, an impurity concentration of an N-type impurity is monotonically increased.

In FIG. 43, an impurity concentration distribution excluding the impurity concentration of the P-type well region 261p and the N-type well region 271n is the same as an impurity concentration distribution of the N-type high voltage transistor Tr_{NHA} according to the modification example of the first embodiment.

### Manufacturing Method

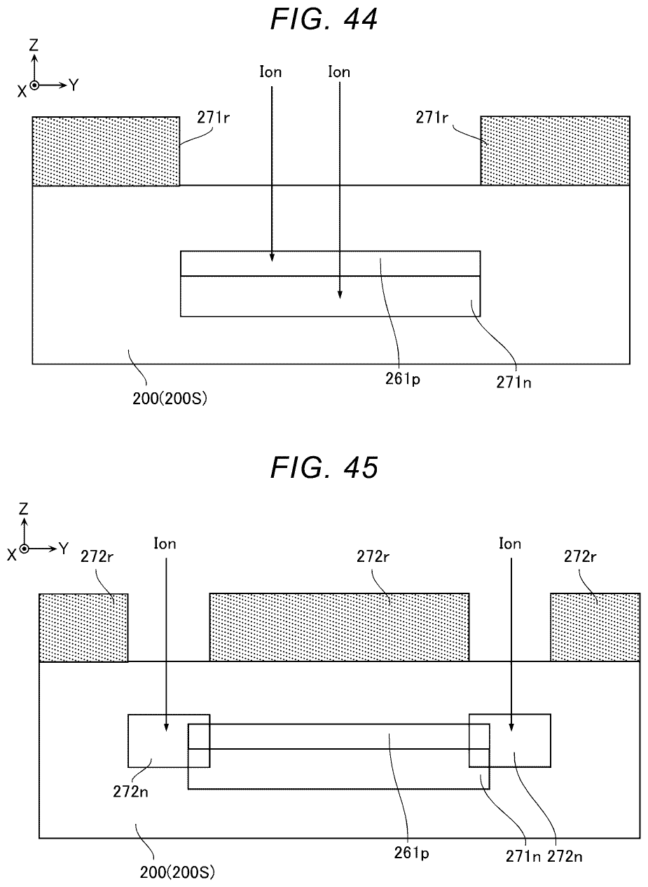

Next, a method of manufacturing the N-type high voltage transistor Tr_{NH2} and the like according to the second embodiment will be described with reference to FIGS. 44 to 49.

First, as shown in FIG. 44, a resist 271r in which a region corresponding to the P− type well region 261p and the N-type well region 271n is opened is formed on the surface of the semiconductor substrate 200. Then, for example, an N-type impurity such as phosphorus (P) is ion-implanted to form the N-type well region 271n, and then, for example, a P-type impurity such as boron (B) is ion-implanted to form the P-type well region 261p.

Next, as shown in FIG. 45, a resist 272r in which a region corresponding to the N− type well region 272n is opened is formed on the surface of the semiconductor substrate 200, and the N-type well region 272n is formed by, for example, ion-implanting an N-type impurity such as phosphorus (P).

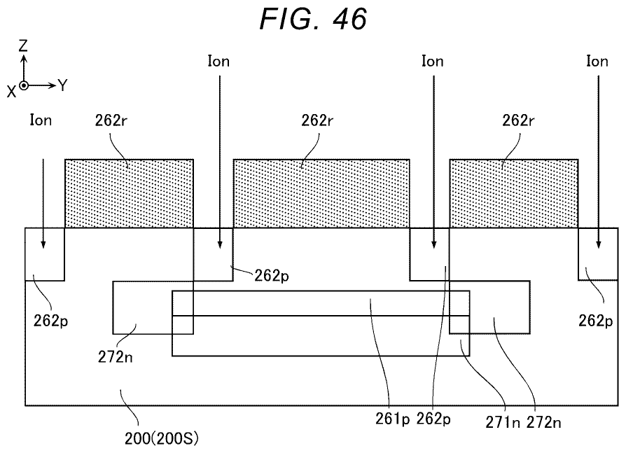

Next, as shown in FIG. 46, a resist 262r in which a region corresponding to the P− type well region 262p is opened is formed on the surface of the semiconductor substrate 200, and the P-type well region 262p is formed by, for example, ion-implanting a P-type impurity such as boron (B).

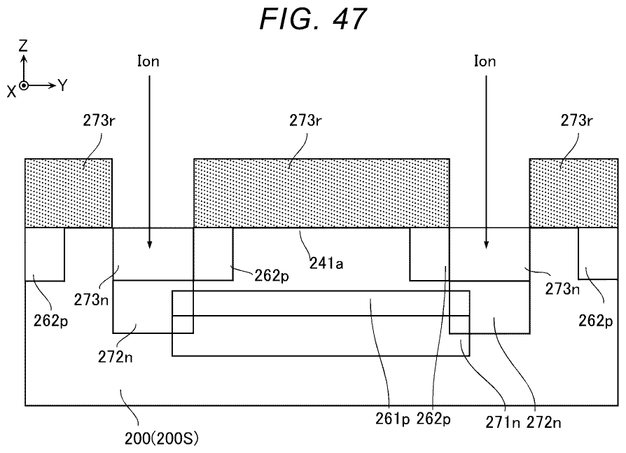

Next, as shown in FIG. 47, a resist 273r in which a region corresponding to the N− type well region 273n is opened is formed on the surface of the semiconductor substrate 200, and the N-type well region 273n is formed by, for example, ion-implanting an N-type impurity such as phosphorus (P). The resist 273r is peeled off.

Next, for example, as shown in FIG. 48, the insulating film 241a such as silicon oxide and the like is formed on the upper surface of the semiconductor substrate 200. This step is performed by, for example, thermal oxidation and the like.

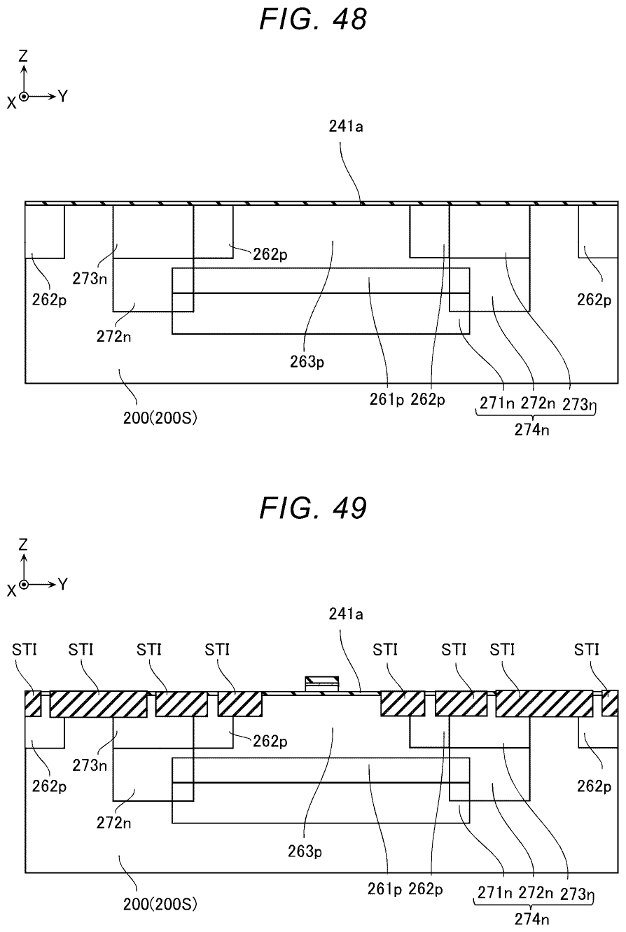

Next, for example, as shown in FIG. 49, the insulating region STI is formed on the semiconductor substrate 200, and a stacked structure corresponding to the gate electrode is formed. This step is executed, for example, in the same manner as that of a step described with reference to FIG. 27 from a step described with reference to FIG. 21. Thereafter, the high voltage transistor Tr_{NH2} according to the second embodiment is manufactured by executing steps after a step described with reference to FIG. 28.

### Effects and the Like of Second Embodiment

When the N-type high voltage transistor Tr_{NH2} provided in the P-type well region 263p electrically separated from the semiconductor substrate 200 does not have the high-concentration N− diffusion layer 202, there is a problem in that a deterioration of the current driving force easily occurs when a voltage of the source region and the drain region is increased with respect to a voltage of the P-type well region 263p.

The reason for this may be considered as follows. That is, by forming the P-type well region 261p in the semiconductor substrate 200, the number of P-type impurities contained in a depletion layer when a high voltage is applied to the source region is increased. Therefore, a parasitic resistance increases because a lower side region of the low-concentration N− diffusion layer 203 in the Z direction and the overlap region that is a region provided at a position where the channel region 206 and the low-concentration N− diffusion layer 203 overlap each other in the Y direction are depleted. In particular, since the overlap region is two-dimensionally depleted in the YZ plane, an increase in the parasitic resistance of the overlap region serves as a main cause of the deterioration of the current driving force.

Meanwhile, in the present embodiment, since the N-type high voltage transistor Tr_{NH2} provided in the P-type well region 263p has the high-concentration N− diffusion layer 202, even when the voltage of the source region and the drain region is increased, the overlap region can be prevented from being depleted, and the current driving force can be prevented from being deteriorated.

Furthermore, since the N-type high voltage transistor Tr_{NH2} has the high-concentration N− diffusion layer 202, even if the low-concentration N− diffusion layer 203 is uniformly made high in concentration, the breakdown voltage can be prevented from being lowered. In addition, since the N-type high voltage transistor Tr_{NH2} has the high-concentration N− diffusion layer 202, the hot carriers (hot electrons) generated by impact ionization can be trapped, and an upper side region of the low-concentration N− diffusion layer 203 in the Z direction can be prevented from being depleted, as in the first embodiment. Therefore, according to the high voltage transistor Tr_{NH2} according to the second embodiment, not only a breakdown voltage deterioration is alleviated, but also an increase in resistance due to a formation of the depletion layer by the trapped hot carriers (hot electrons) is alleviated.

### Other Embodiments

In the above-described embodiment, a technique applied to a NAND flash memory is described. Meanwhile, the techniques described in the present specification may be applied to configurations other than the semiconductor memory device such as a three-dimensional NOR flash memory. In addition, the techniques described in the present specification may also be applied to the configuration of a semiconductor device other than the semiconductor memory device.

### OTHERS

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a semiconductor substrate; and
a plurality of transistors provided on the semiconductor substrate, wherein
a first transistor among the plurality of transistors includes
a first gate insulating film provided on the semiconductor substrate,
a first gate electrode provided on the first gate insulating film,
a side wall insulating film provided on both side surfaces of the first gate electrode,
a first region disposed in the semiconductor substrate and provided at a position overlapping the first gate electrode when viewed in a first direction intersecting a surface of the semiconductor substrate,
a first diffusion layer disposed in the semiconductor substrate, connected to a first contact electrode extending in the first direction, and containing a first conductive-type impurity,
a second diffusion layer disposed in the semiconductor substrate, provided between the first region and the first diffusion layer, and containing the first conductive-type impurity, and
a third diffusion layer disposed in the semiconductor substrate, provided between the second diffusion layer and the first diffusion layer, connected to the second diffusion layer, and containing the first conductive-type impurity, and
a concentration of the first conductive-type impurity in the second diffusion layer is higher than a concentration of the first conductive-type impurity in the third diffusion layer.

2. The semiconductor memory device according to claim 1, wherein
the first transistor is an N-channel transistor.

3. The semiconductor memory device according to claim 1, wherein
the first conductive-type impurity is an N-type impurity.

4. The semiconductor memory device according to claim 1, wherein
at least a part of the second diffusion layer is provided at a position overlapping the side wall insulating film when viewed in the first direction.

5. The semiconductor memory device according to claim 1, wherein
the concentration of the first conductive-type impurity in the second diffusion layer is higher than the concentration of the first conductive-type impurity in the third diffusion layer by less than 10 times.

6. The semiconductor memory device according to claim 1, wherein
a concentration of the first conductive-type impurity in the first diffusion layer is 10 times the concentration of the first conductive-type impurity in the second diffusion layer or more.

7. The semiconductor memory device according to claim 1, further comprising:
a first insulating layer provided on both side surfaces of the first gate electrode with the side wall insulating film sandwiched therebetween and containing silicon (Si) and oxygen (O); and
a second insulating layer provided on both side surfaces of the first gate electrode with the first insulating layer sandwiched therebetween and containing silicon (Si) and nitrogen (N).

8. The semiconductor memory device according to claim 1, further comprising:
a fourth diffusion layer disposed in the semiconductor substrate, provided at a position overlapping the third diffusion layer when viewed in the first direction, located on a side opposite to the first gate electrode in the first direction with respect to the third diffusion layer, and containing a second conductive-type impurity.

9. The semiconductor memory device according to claim 1, wherein
the semiconductor substrate includes
a first well containing a second conductive-type impurity, and
a second well surrounding the first well when viewed in the first direction and containing the first conductive-type impurity, and
the first region, the first diffusion layer, the second diffusion layer, and the third diffusion layer are provided in the first well.

10. The semiconductor memory device according to claim 1, wherein
during operation of the semiconductor memory device, a voltage higher than 10 V is supplied to the first transistor.

11. The semiconductor memory device according to claim 1, wherein
a second transistor among the plurality of transistors includes
a second gate insulating film provided on the semiconductor substrate, and
a second gate electrode provided on the second gate insulating film, and
a length of the first gate insulating film in the first direction is longer than a length of the second gate insulating film in the first direction.

12. The semiconductor memory device according to claim 1, wherein
a second transistor among the plurality of transistors includes
a second gate insulating film provided on the semiconductor substrate,
a second gate electrode provided on the second gate insulating film,
a second region disposed in the semiconductor substrate and provided at a position overlapping the second gate electrode when viewed in the first direction, and
a fifth diffusion layer provided in the semiconductor substrate, connected to a second contact electrode extending in the first direction, and containing the first conductive-type impurity, and
a distance from the first region to the first contact electrode is greater than a distance from the second region to the second contact electrode.

13. The semiconductor memory device according to claim 1, further comprising:
a plurality of conductive layers arranged in the first direction;
a semiconductor layer extending in the first direction and facing the plurality of conductive layers;
a charge storage film provided between the plurality of conductive layers and the semiconductor layer; and
a voltage generation circuit electrically connected to the plurality of conductive layers, wherein
the first transistor is provided in a current path between the plurality of conductive layers and the voltage generation circuit.

14. The semiconductor memory device according to claim 1, wherein a thickness of a first gate insulating film in the first direction is about 35 nm to about 50 nm.

15. A semiconductor memory device comprising:
a semiconductor substrate; and
a plurality of transistors provided on the semiconductor substrate, wherein
a first transistor among the plurality of transistors includes
a first gate insulating film provided on the semiconductor substrate,
a first gate electrode provided on the first gate insulating film,
a side wall insulating film provided on both side surfaces of the first gate electrode,
a first region disposed in the semiconductor substrate and provided at a position overlapping the first gate electrode when viewed in a first direction intersecting a surface of the semiconductor substrate,
one diffusion layer disposed in the semiconductor substrate, provided at a position overlapping the side wall insulating film when viewed in the first direction, and containing a first conductive-type impurity, and
another diffusion layer provided on a side opposite to the first region in a second direction intersecting the first direction with respect to the one diffusion layer, connected to the one diffusion layer, and containing the first conductive-type impurity, and
a concentration of the first conductive-type impurity in the one diffusion layer is higher than a concentration of the first conductive-type impurity in the other diffusion layer.

16. The semiconductor memory device according to claim 15, wherein
the first transistor is an N-channel transistor.

17. The semiconductor memory device according to claim 15, wherein
the first conductive-type impurity is an N-type impurity.

18. The semiconductor memory device according to claim 15, wherein
the concentration of the first conductive-type impurity in the one diffusion layer is higher than the concentration of the first conductive-type impurity in the other diffusion layer by less than 10 times.

19. The semiconductor memory device according to claim 15, further comprising:
a first insulating layer provided on both side surfaces of the first gate electrode with the side wall insulating film sandwiched therebetween and containing silicon (Si) and oxygen (O); and
a second insulating layer provided on both side surfaces of the first gate electrode with the first insulating layer sandwiched therebetween and containing silicon (Si) and nitrogen (N).

20. The semiconductor memory device according to claim 15, wherein a thickness of a first gate insulating film in the first direction is about 35 nm to about 50 nm.
